(19) United States
(12) Patent Application Publication
(10) Pub. No.: US 2024/0324195 A1
(43) Pub. Date: Sep. 26, 2024

(54) SEMICONDUCTOR DEVICE MANUFACTURING METHOD

(71) Applicant: Kioxia Corporation, Tokyo (JP)

(72) Inventors: Hakuba KITAGAWA, Yokkaichi (JP); Mariko SUMIYA, Yokkaichi (JP); Kohei NAKAMURA, Yokkaichi (JP); Hiroaki ASHIDATE, Mie (JP); Jun TAKAGI, Yokkaichi (JP); Masayuki FUKUMOTO, Yokkaichi (JP)

(73) Assignee: Kioxia Corporation, Tokyo (JP)

(21) Appl. No.: 18/612,553

(22) Filed: Mar. 21, 2024

(30) Foreign Application Priority Data
Mar. 23, 2023 (JP) 2023-046865

(51) Int. Cl. H10B 41/35; H10B 41/10; H10B 41/20

(52) U.S. Cl. CPC H10B 41/35; H10B 41/10; H10B 41/20

(57) ABSTRACT

A semiconductor device manufacturing method of embodiments includes: forming an insulating film on an outer peripheral portion of a surface of a first substrate; after forming the insulating film, forming a silicon layer in contact with the surface inside the insulating film; and forming a porous silicon layer by making the silicon layer inside the insulating film porous using an anodization method.

### CROSS-REFERENCE TO RELATED APPLICATION

This application is based upon and claims the benefit of priority from Japanese Patent Application No. 2023-046865, filed on Mar. 23, 2023, the entire contents of which are incorporated herein by reference.

### FIELD

Embodiments described herein relate generally to a semiconductor device manufacturing method.

### BACKGROUND

A highly functional or highly integrated semiconductor device can be realized, for example, by bonding a support substrate on which a first electronic circuit is formed and a semiconductor substrate on which a second electronic circuit is formed. After bonding the support substrate and the semiconductor substrate together, the support substrate is separated and reused, for example, in order to reduce the manufacturing cost of the semiconductor device.

### BRIEF DESCRIPTION OF THE DRAWINGS

FIGS. 1A, 1B, 1C, and 1D are explanatory diagrams of a semiconductor device manufacturing method according to a first embodiment;

FIGS. 2A and 2B are explanatory diagrams of the semiconductor device manufacturing method according to the first embodiment;

FIGS. 3A, 3B, and 3C are explanatory diagrams of the semiconductor device manufacturing method according to the first embodiment;

FIG. 4 is an explanatory diagram of the semiconductor device manufacturing method according to the first embodiment;

FIGS. 5A and 5B are explanatory diagrams of the semiconductor device manufacturing method according to the first embodiment;

FIGS. 6A and 6B are explanatory diagrams of the semiconductor device manufacturing method according to the first embodiment;

FIGS. 7A and 7B are explanatory diagrams of the semiconductor device manufacturing method according to the first embodiment;

FIG. 8 is an explanatory diagram of the semiconductor device manufacturing method according to the first embodiment;

FIG. 9 is an explanatory diagram of the semiconductor device manufacturing method according to the first embodiment;

FIGS. 10A, 10B, and 10C are explanatory diagrams of a semiconductor device manufacturing method according to a comparative example;

FIG. 11 is an explanatory diagram of the semiconductor device manufacturing method according to the comparative example;

FIGS. 12A and 12B are explanatory diagrams of the function and effect of the semiconductor device manufacturing method according to the first embodiment;

FIGS. 13A and 13B are explanatory diagrams of a semiconductor device manufacturing method according to a first modification example of the first embodiment;

FIGS. 14A, 14B, and 14C are explanatory diagrams of a semiconductor device manufacturing method according to a second modification example of the first embodiment;

FIGS. 15A, 15B, 15C, and 15D are explanatory diagrams of a semiconductor device manufacturing method according to a second embodiment;

FIGS. 16A, 16B, and 16C are explanatory diagrams of the semiconductor device manufacturing method according to the second embodiment;

FIGS. 17A, 17B, 17C, and 17D are explanatory diagrams of a semiconductor device manufacturing method according to a modification example of the second embodiment;

FIGS. 18A, 18B, 18C, and 18D are explanatory diagrams of a semiconductor device manufacturing method according to a third embodiment;

FIGS. 19A and 19B are explanatory diagrams of the semiconductor device manufacturing method according to the third embodiment;

FIGS. 20A and 20B are explanatory diagrams of the semiconductor device manufacturing method according to the third embodiment;

FIGS. 21A, 21B, 21C, and 21D are explanatory diagrams of a semiconductor device manufacturing method according to a first modification example of the third embodiment;

FIGS. 22A and 22B are explanatory diagrams of the semiconductor device manufacturing method according to the first modification example of the third embodiment;

FIGS. 23A and 23B are explanatory diagrams of the semiconductor device manufacturing method according to the first modification example of the third embodiment;

FIGS. 24A and 24B are explanatory diagrams of the semiconductor device manufacturing method according to the first modification example of the third embodiment;

FIGS. 25A, 25B, 25C, and 25D are explanatory diagrams of a semiconductor device manufacturing method according to a second modification example of the third embodiment;

FIGS. 26A and 26B are explanatory diagrams of the semiconductor device manufacturing method according to the second modification example of the third embodiment;

FIGS. 27A and 27B are explanatory diagrams of the semiconductor device manufacturing method according to the second modification example of the third embodiment;

FIGS. 28A, 28B, 28C, 28D, and 28E are explanatory diagrams of a semiconductor device manufacturing method according to a fourth embodiment;

FIGS. 29A, 29B, and 29C are explanatory diagrams of the semiconductor device manufacturing method according to the fourth embodiment;

FIGS. 30A, 30B, 30C are explanatory diagrams of the semiconductor device manufacturing method according to the fourth embodiment;

FIGS. 31A and 31B are explanatory diagrams of the semiconductor device manufacturing method according to the fourth embodiment;

FIGS. 32A, 32B, 32C, and 32D are explanatory diagrams of a semiconductor device manufacturing method according to a fifth embodiment;

FIGS. 33A, 33B, 33C, and 33D are explanatory diagrams of the semiconductor device manufacturing method according to the fifth embodiment; and

FIGS. 34A and 34B are explanatory diagrams of the semiconductor device manufacturing method according to the fifth embodiment.

### DETAILED DESCRIPTION

A semiconductor device manufacturing method of embodiments includes: forming an insulating film on an outer peripheral portion of a surface of a first substrate; forming a silicon layer in contact with the surface inside the insulating film after the forming the insulating film; and forming a porous silicon layer by making the silicon layer inside the insulating film porous using an anodization method.

Hereinafter, embodiments will be described with reference to the diagrams. In addition, in the following description, the same or similar members and the like are denoted by the same reference numerals, and the description of the members and the like once described will be omitted as appropriate.

In addition, in this specification, the term “upper” or “lower” may be used for convenience. “Upper” or “lower” is a term indicating, for example, a relative positional relationship in the diagrams. The term “upper” or “lower” does not necessarily define the positional relationship with respect to gravity.

The qualitative analysis and quantitative analysis of the chemical composition of the members forming the semiconductor device in this specification can be performed by using, for example, secondary ion mass spectrometry (SIMS) and energy dispersive X-ray spectroscopy (EDX). In addition, when measuring the thickness of each member forming the semiconductor device, a distance between members, and the like, for example, a scanning electron microscope (SEM) can be used.

### First Embodiment

A semiconductor device manufacturing method according to a first embodiment includes: forming an insulating film on an outer peripheral portion of a surface of a first substrate; after forming the insulating film, forming a silicon layer in contact with the surface inside the insulating film; and forming a porous silicon layer by making the silicon layer inside the insulating film porous using an anodization method.

The semiconductor device manufacturing method according to the first embodiment is a method for manufacturing a semiconductor device by bonding two substrates together. The semiconductor device is, for example, a semiconductor memory. The semiconductor memory is, for example, a three-dimensional NAND flash memory in which memory cells are arranged in a three-dimensional manner.

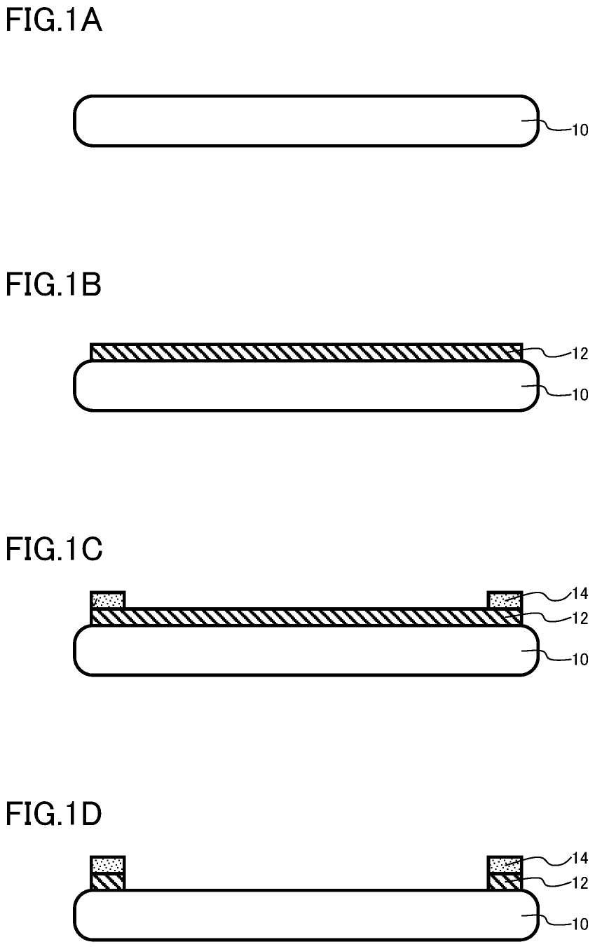

FIGS. 1A, 1B, 1C, 1D, 2A, 2B, 3A, 3B, 3C, 4, 5A, 5B, 6A, 6B, 7A, 7B, 8, and 9 are explanatory diagrams of the semiconductor device manufacturing method according to the first embodiment.

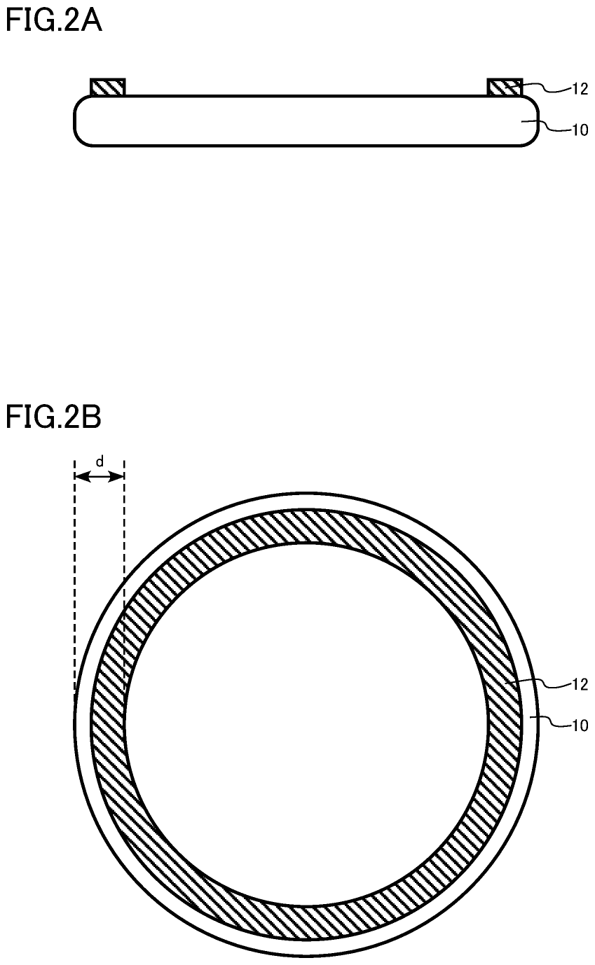

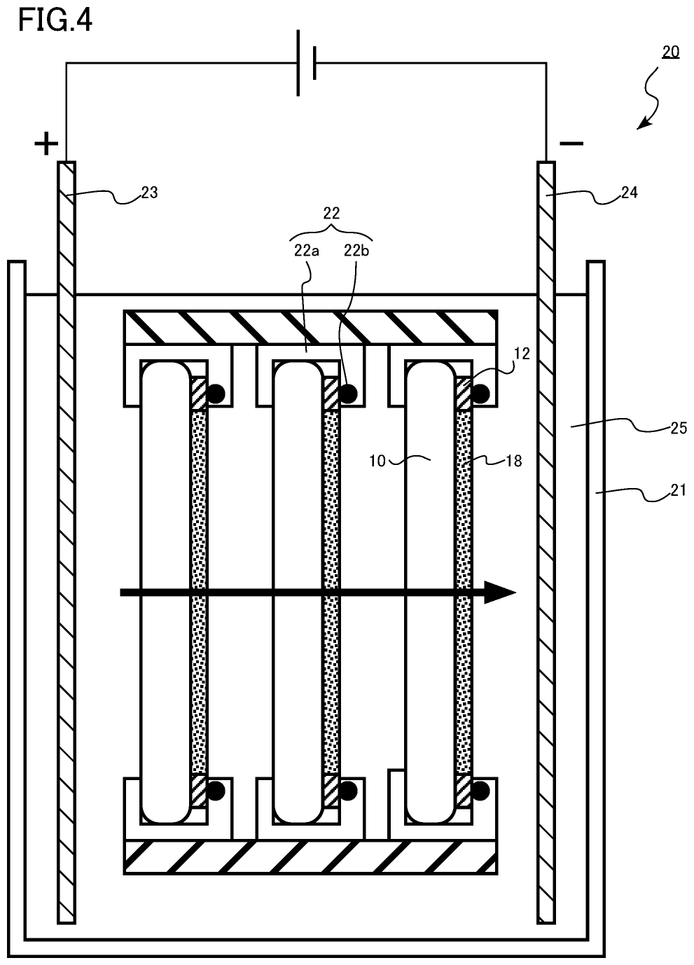

FIGS. 1A, 1B, 1C, 1D, 2A, 3A, 3B, 3C, 5A, 5B, 6A, 6B, 7A, 7B, 8, and 9 are schematic cross-sectional views. FIG. 2B is a schematic top view. FIG. 4 is a schematic diagram of an example of an anodization apparatus.

First, a support substrate 10 is prepared (FIG. 1A). The support substrate 10 is an example of the first substrate.

The support substrate 10 is a conductor. The support substrate 10 is, for example, a semiconductor. The support substrate 10 is, for example, a single crystal silicon. The support substrate 10 is, for example, a silicon substrate. The support substrate 10 is, for example, a p-type silicon substrate containing boron (B) as a p-type impurity. The support substrate 10 is, for example, a silicon wafer. The support substrate 10 is, for example, a p-type silicon wafer containing boron (B) as a p-type impurity. The support substrate 10 may be, for example, an insulating substrate such as a quartz substrate.

The diameter of the support substrate 10 is, for example, equal to or more than 150 mm and equal to or less than 300 mm.

Then, an insulating film 12 is formed on the surface of the support substrate 10 (FIG. 1B). The insulating film 12 is formed by using, for example, a chemical vapor deposition method (CVD method).

The insulating film 12 is, for example, an oxide, a nitride, an oxynitride, or a carbide. The insulating film 12 is, for example, a silicon oxide, a silicon nitride, or a nitrogen-doped silicon carbide.

The thickness of the insulating film 12 is, for example, equal to or more than 100 nm and equal to or less than 10 μm.

Then, a photoresist film 14 is formed so as to cover the insulating film 12 on the outer peripheral portion of the support substrate 10 (FIG. 1C). For example, the photoresist film 14 is formed by patterning using a photolithography method.

For example, when a positive resist is used as the photoresist film 14, the photoresist film 14 is applied to the surface of the support substrate 10, and then sensitizing the photoresist film 14 by exposing the central portion of the support substrate 10 to light, thereby removing the photoresist film 14 on the central portion of the support substrate 10.

In addition, for example, when a negative resist is used as the photoresist film 14, the photoresist film 14 is applied to the surface of the support substrate 10, and then sensitizing the photoresist film 14 by exposing the outer peripheral portion of the support substrate 10 to light, thereby removing the photoresist film 14 on the central portion of the support substrate 10.

Then, using the patterned photoresist film 14 as a mask, the insulating film 12 on the central portion of the support substrate 10 is removed (FIG. 1D). The insulating film 12 is removed by using, for example, a wet etching method.

Then, the photoresist film 14 is removed (FIG. 2A). As shown in FIGS. 2A and 2B, the insulating film 12 having an annular shape is formed on the outer peripheral portion of the support substrate 10.

The distance (d in FIG. 2B) from the outer edge of the support substrate 10 to the inner edge of the annular insulating film 12 is, for example, equal to or more than 1 mm and equal to or less than 10 mm. In FIG. 2B, the outer edge of the insulating film 12 may match the outer edge of the support substrate 10.

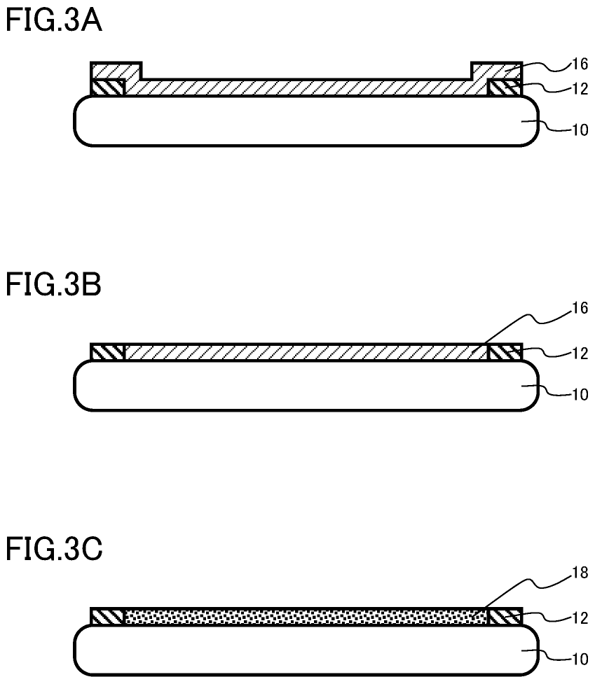

Then, a polycrystalline silicon layer 16 is formed on the surface of the support substrate 10 (FIG. 3A). The polycrystalline silicon layer 16 is an example of a silicon layer. The polycrystalline silicon layer 16 is formed inside the insulating film 12 so as to be in contact with the surface of the support substrate 10.

The polycrystalline silicon layer 16 is formed by using, for example, a CVD method. The thickness of the polycrystalline silicon layer 16 is, for example, equal to or more than 100 nm and equal to or less than 10 μm.

Then, the polycrystalline silicon layer 16 formed on the insulating film 12 is removed (FIG. 3B). The polycrystalline silicon layer 16 is removed by using, for example, a chemical mechanical polishing method (CMP method).

Then, the polycrystalline silicon layer 16 inside the insulating film 12 is made porous using an anodization method (FIG. 3C). By making the polycrystalline silicon layer 16 porous, a porous silicon layer 18 is formed inside the insulating film 12. The porous silicon layer 18 has a void.

FIG. 4 is a schematic diagram of an example of an anodization apparatus 20 used when making the polycrystalline silicon layer 16 porous. FIG. 4 illustrates a state in which the support substrate 10 is processed.

As shown in FIG. 4, the anodization apparatus 20 includes a processing tank 21, a substrate holder 22, a first electrode 23, and a second electrode 24. The anodization apparatus 20 is, for example, a batch type apparatus that can process a plurality of substrates simultaneously.

The processing tank 21 is, for example, a container formed of fluororesin. An electrolyte 25 is stored in the processing tank 21. The electrolyte 25 contains, for example, hydrofluoric acid.

The substrate holder 22 holds the support substrate 10 and covers an outer region of the support substrate. The substrate holder 22 has a support portion 22a and a sealing portion 22b. The sealing portion 22b has a function of blocking the flow path of the electrolyte from one surface of the support substrate 10 to the other surface. The sealing portion 22b is, for example, an O-ring.

A voltage is applied between the first electrode 23 and the second electrode 24. For example, a positive voltage is applied to the first electrode 23 and a negative voltage is applied to the second electrode 24. In this case, the first electrode 23 becomes a positive electrode and the second electrode 24 becomes a negative electrode. As shown by the arrow in FIG. 4, a current flows to the electrolyte 25 between the first electrode 23 and the second electrode 24 through the support substrate 10.

The silicon layer on the cathode side of the support substrate 10, that is, on the side of the second electrode 24 of the support substrate 10 held in the electrolyte 25, becomes porous by anodization, so that the porous silicon layer 18 is formed. The insulating film 12 has a higher resistance value than the polycrystalline silicon layer 16, the insulating film 12 is less likely to be made porous.

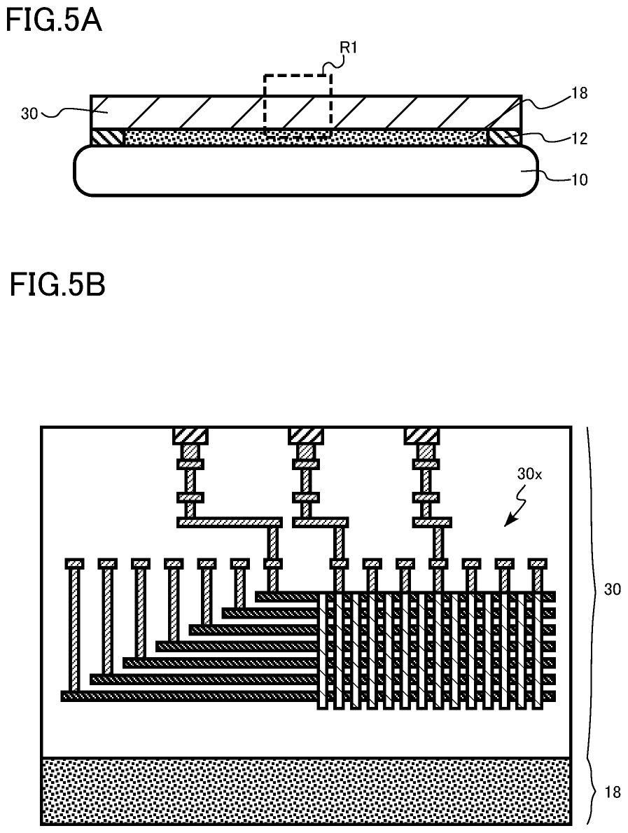

After forming the porous silicon layer 18 by making the polycrystalline silicon layer 16 porous, a memory layer 30 is formed on the porous silicon layer 18 (FIG. 5A). The memory layer 30 is formed by using a known process technique.

FIG. 5B is an enlarged view of a region R1 surrounded by the broken line in FIG. 5A. As shown in FIG. 5B, the memory layer 30 includes a memory cell array 30x having a plurality of memory cells. The plurality of memory cells are arranged, for example, in a three-dimensional manner within the memory cell array 30x. The memory cells included in the memory cell array 30x are, for example, three-terminal nonvolatile memory cells.

The memory cell array 30x is an example of the first electronic circuit.

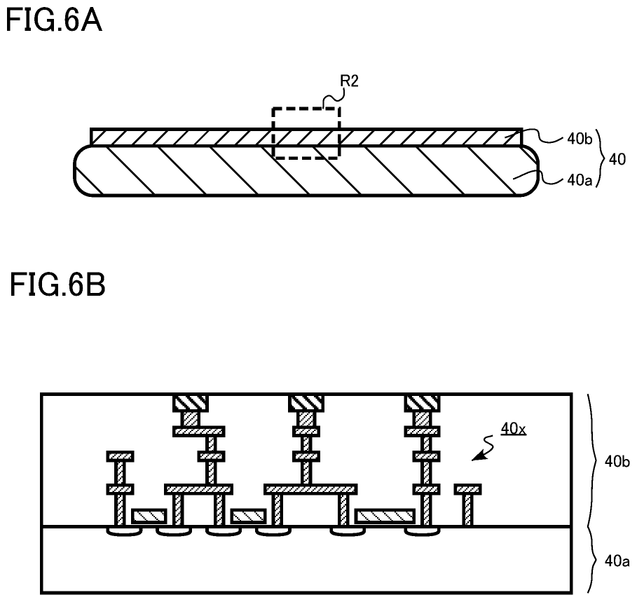

Then, a semiconductor substrate 40 is prepared (FIG. 6A). The semiconductor substrate 40 is an example of the second substrate.

FIGS. 6A and 6B are schematic cross-sectional views of the semiconductor substrate 40. FIG. 6B is an enlarged schematic cross-sectional view of a part of the semiconductor substrate 40. FIG. 6B is an enlarged view of a region R2 surrounded by the broken line in FIG. 6A.

As shown in FIG. 6B, the semiconductor substrate 40 includes, for example, a semiconductor layer 40a and a wiring layer 40b. The semiconductor layer 40a is, for example, a single crystal silicon. Examples of the semiconductor substrate 40 include a silicon substrate. The semiconductor substrate 40 is, for example, a silicon wafer. The semiconductor substrate 40 is, for example, a p-type silicon wafer containing boron (B) as a p-type impurity.

The semiconductor substrate 40 includes a control circuit 40x. The control circuit 40x is an example of the second electronic circuit.

The control circuit 40x is formed by the semiconductor layer 40a and the wiring layer 40b. The control circuit 40x is formed by, for example, transistors and multilayer wiring connecting the transistors to each other. The control circuit 40x is, for example, a CMOS circuit including an n-type transistor and a p-type transistor.

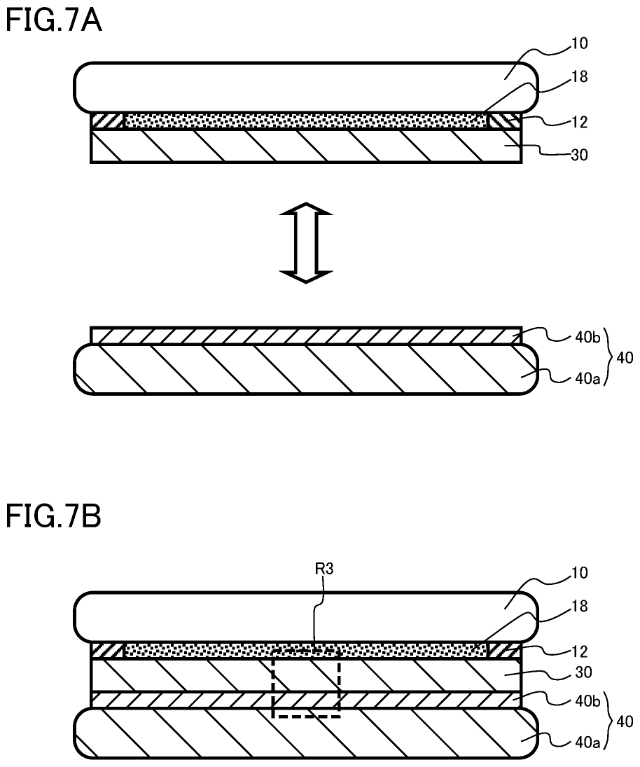

Then, as shown in FIG. 7A, the wiring layer 40b of the semiconductor substrate 40 and the memory layer 30 are made to face each other.

Then, as shown in FIG. 7B, the support substrate 10 and the semiconductor substrate 40 are bonded together. The memory layer 30 formed on the support substrate 10 and the wiring layer 40b of the semiconductor substrate 40 are bonded together so as to be in contact with each other. The support substrate 10 and the semiconductor substrate 40 are bonded together so that the memory cell array 30x of the memory layer 30 and the control circuit 40x of the semiconductor substrate 40 are physically and electrically connected to each other.

For example, mechanical pressure is applied between the support substrate 10 and the semiconductor substrate 40. For example, by applying heat treatment while applying mechanical pressure, the memory layer 30 and the wiring layer 40b are bonded together. The temperature of the heat treatment is, for example, equal to or more than 300° C. and equal to or less than 500° C. By applying heat treatment while applying mechanical pressure between the support substrate 10 and the semiconductor substrate 40, the strength of the bonding surface between the support substrate 10 and the semiconductor substrate 40 is increased.

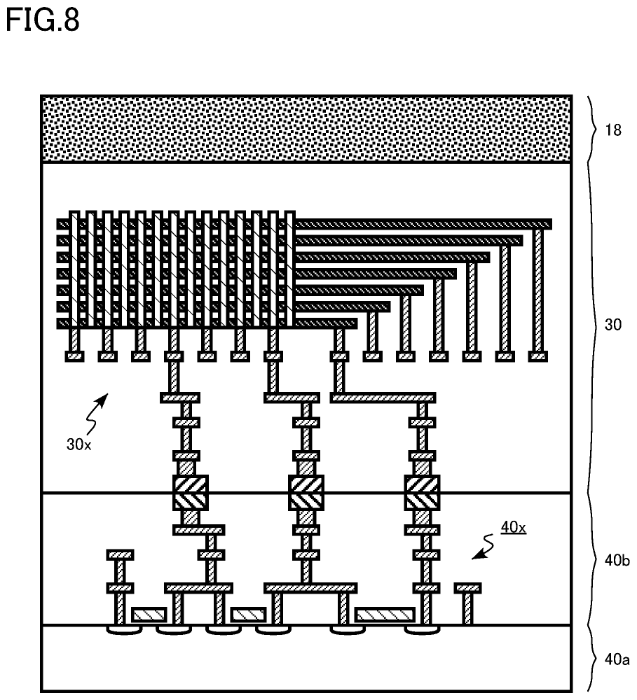

FIG. 8 is an enlarged view of a region R3 surrounded by the broken line in FIG. 7B. By bonding the memory layer 30 and the wiring layer 40b together, the memory cell array 30x and the control circuit 40x are electrically connected to each other. The control circuit 40x has, for example, a function of controlling the operation of the memory cell array 30x.

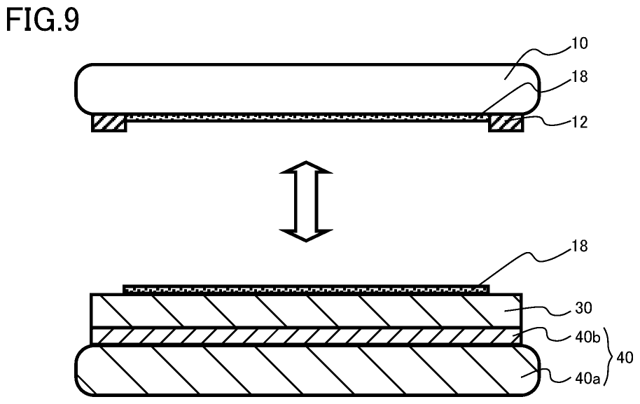

Then, as shown in FIG. 9, the support substrate 10 and the semiconductor substrate 40 are separated from each other with the porous silicon layer 18 as a boundary. That is, the support substrate 10 and the memory layer 30 are separated from each other with the porous silicon layer 18 as a boundary. That is, the support substrate 10 and the memory cell array 30x are separated from each other with the porous silicon layer 18 as a boundary.

For example, by pressing a wedge-shaped jig from the side toward the boundary between the memory layer 30 and the wiring layer 40b and/or spraying a water jet, the porous silicon layer 18 is mechanically divided with the boundary between the memory layer 30 and the wiring layer 40b as a starting point so that the support substrate 10 and the semiconductor substrate 40 are separated from each other.

The porous silicon layer 18 remaining on the separated semiconductor substrate 40 is removed by using, for example, a CMP method.

Then, the semiconductor substrate 40 and the memory layer 30 bonded together are divided into a plurality of semiconductor memory chips by using, for example, a blade dicing method.

The porous silicon layer 18 or the insulating film 12 remaining on the separated support substrate 10 is removed by using, for example, a CMP method. Then, the support substrate 10 can be reused for manufacturing semiconductor devices.

By the semiconductor device manufacturing method described above, the support substrate 10 and the semiconductor substrate 40 are bonded together to manufacture the three-dimensional NAND flash memory according to the first embodiment.

Next, the function and effect of the semiconductor device manufacturing method according to the first embodiment will be described.

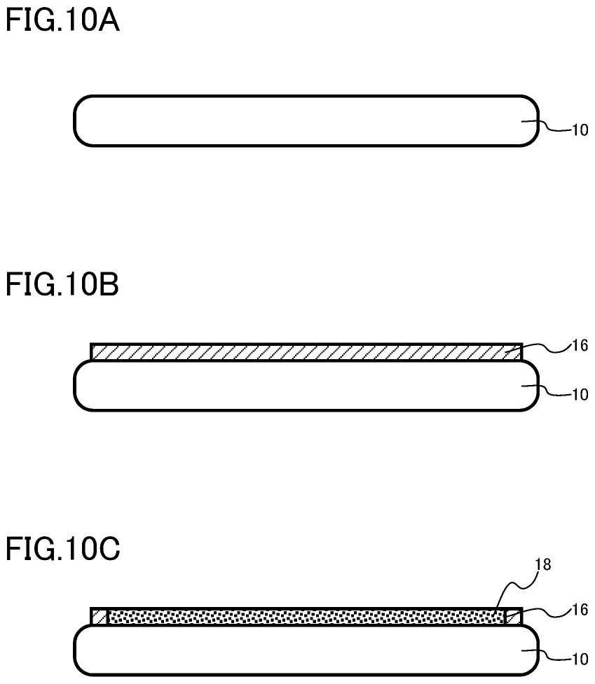

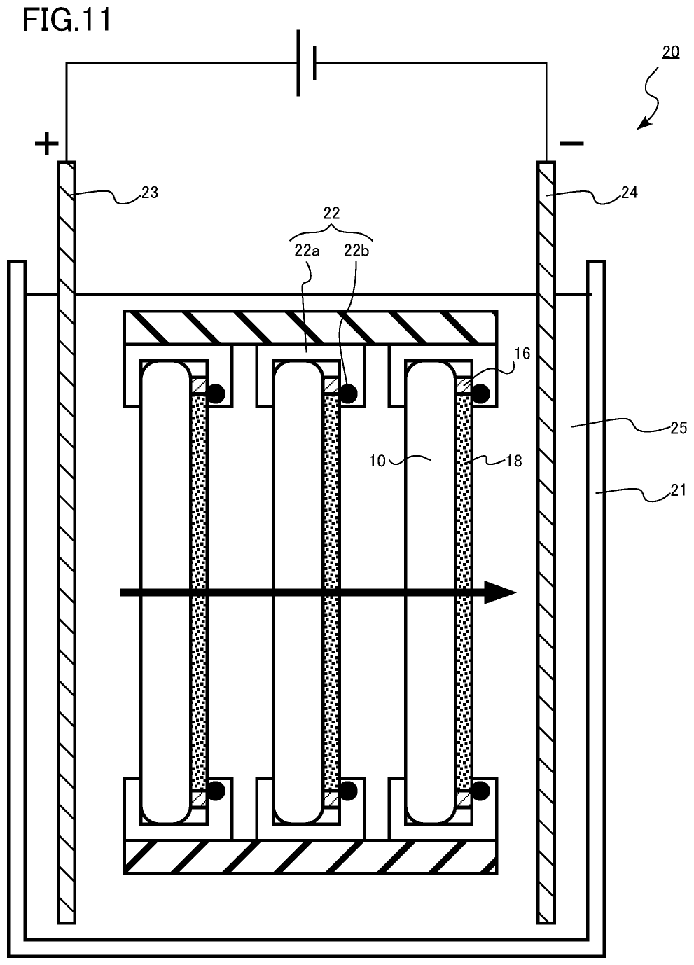

FIGS. 10A, 10B, 10C, and 11 are explanatory diagrams of a semiconductor device manufacturing method according to a comparative example.

FIGS. 10A, 10B, and 10C are schematic cross-sectional views. FIG. 11 is a schematic diagram of an example of an anodization apparatus.

The semiconductor device manufacturing method according to the comparative example is different from the semiconductor device manufacturing method according to the first embodiment in that the annular insulating film 12 is not formed on the outer peripheral portion of the support substrate 10.

First, the support substrate 10 is prepared (FIG. 10A). The support substrate 10 is, for example, a silicon substrate.

Then, the polycrystalline silicon layer 16 is formed on the surface of the support substrate 10 (FIG. 10B). The polycrystalline silicon layer 16 is formed by using, for example, a CVD method.

Then, the polycrystalline silicon layer 16 is made porous using an anodization method (FIG. 10C). By making the polycrystalline silicon layer 16 porous, the porous silicon layer 18 is formed. The porous silicon layer 18 has a void inside. The outermost periphery of the polycrystalline silicon layer 16 remains without being made porous.

FIG. 11 is a schematic diagram of an example of the anodization apparatus 20 used when making the polycrystalline silicon layer 16 porous. The anodization apparatus 20 has the same apparatus configuration as the apparatus used in the semiconductor device manufacturing method according to the first embodiment.

As in the case of the first embodiment, the silicon layer on the cathode side of the support substrate 10, that is, on the side of the second electrode 24 of the support substrate 10 held in the electrolyte, becomes porous by anodization, so that the porous silicon layer 18 is formed.

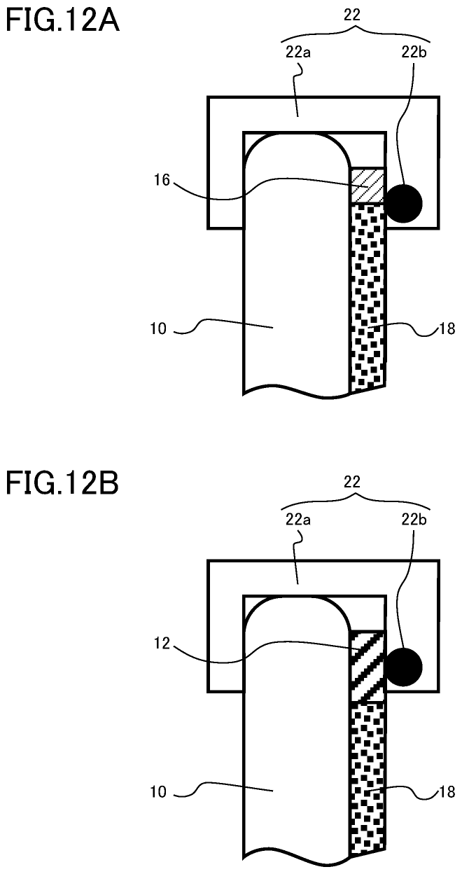

FIGS. 12A and 12B are explanatory diagrams of the function and effect of the semiconductor device manufacturing method according to the first embodiment. FIGS. 12A and 12B are enlarged views of a part of the substrate holder 22 of the anodization apparatus 20. FIG. 12A is a diagram when the support substrate 10 in the comparative example is processed, and FIG. 12B is a diagram when the support substrate 10 in the first embodiment is processed.

The substrate holder 22 has a support portion 22a and a sealing portion 22b. The sealing portion 22b has a function of blocking the flow path of the electrolyte from one surface of the support substrate 10 to the other surface. The sealing portion 22b blocks the flow path of the electrolyte to suppress the flow of current to the outer edge of the support substrate 10, and accordingly the current flows through the support substrate 10.

As shown in FIG. 12A, in the case of the comparative example, since the flow path of the electrolyte is blocked by the sealing portion 22b, the polycrystalline silicon layer 16 located closer to the outer peripheral side of the support substrate 10 than the sealing portion 22b does not become porous. Therefore, the outermost periphery of the polycrystalline silicon layer 16 remains without being made porous. On the other hand, a current flows through the polycrystalline silicon layer 16 inside the sealing portion 22b, making the polycrystalline silicon layer 16 porous. As a result, the porous silicon layer 18 is formed. In other words, in the case of the comparative example, the position of the outer peripheral end of the porous silicon layer 18 is determined by the contact position of the sealing portion 22b.

The memory layer 30 is formed on the support substrate 10 on which the porous silicon layer 18 is formed. To form the memory layer 30, the support substrate 10 is processed in various kinds of semiconductor manufacturing equipment. When the support substrate 10 is processed, the outermost peripheral portion of the support substrate 10 may come into contact with, for example, a transport jig or carrier of semiconductor manufacturing equipment.

For example, if the mechanically fragile porous silicon layer 18 comes into contact with a transport jig or carrier, dust may be generated. When dust is generated, for example, the manufacturing yield of semiconductor devices decreases, which causes a problem. Therefore, it is preferable that the porous silicon layer 18 is not formed in a predetermined range of the outer peripheral portion of the support substrate 10.

As described above, in the case of the comparative example, the position of the outer peripheral end of the porous silicon layer 18 is determined by the contact position of the sealing portion 22b. For example, when holding the support substrate 10 on the substrate holder 22, if a misalignment of the support substrate 10 with respect to the substrate holder 22 occurs, the position where the sealing portion 22b is in contact with the support substrate 10 changes. Therefore, there is a risk that the porous silicon layer 18 will be formed in a region beyond the predetermined range of the outer peripheral portion of the support substrate 10.

In addition, in the case of the comparative example, for example, the sealing of the electrolyte flow path by the sealing portion 22b may be insufficient, and accordingly the electrolyte may enter between the sealing portion 22b and the support substrate 10. When the electrolyte enters, there is a risk that a current will flow through the polycrystalline silicon layer 16 located closer to the outer peripheral portion of the support substrate 10 than the sealing portion 22b and the porous silicon layer 18 will be formed in a region beyond the predetermined range of the outer peripheral portion of the support substrate 10.

As described above, in the case of the comparative example, the porous silicon layer 18 may become a cause of dust generation due to variations in the position of the outer peripheral end of the porous silicon layer 18.

In the case of the first embodiment, the position of the outer peripheral end of the porous silicon layer 18 is determined by the inner peripheral end of the insulating film 12 provided annularly on the outer peripheral portion of the support substrate 10. Therefore, even if a misalignment of the support substrate 10 with respect to the substrate holder 22 occurs or the electrolyte enters between the sealing portion 22b and the support substrate 10, the position of the outer peripheral end of the porous silicon layer 18 does not change. As a result, since the position of the outer peripheral end of the porous silicon layer 18 is stabilized, it is possible to prevent the porous silicon layer 18 from becoming a cause of dust generation.

In the semiconductor device manufacturing method according to the first embodiment, the position of the outer peripheral end of the porous silicon layer 18 is stabilized. Therefore, according to the semiconductor device manufacturing method according to the first embodiment, it is possible to stabilize the manufacturing process for a semiconductor device manufactured by bonding the support substrate 10 and the semiconductor substrate 40 together.

### First Modification Example

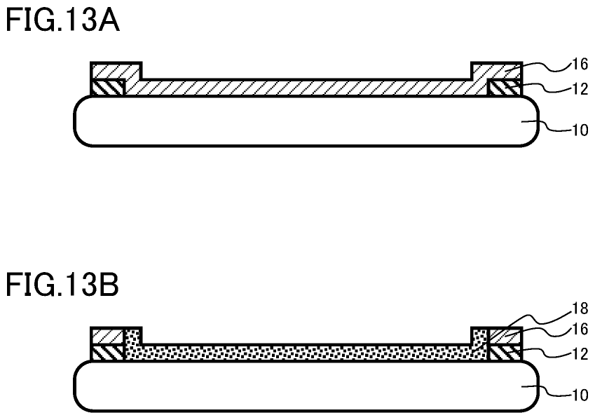

FIGS. 13A and 13B are explanatory diagrams of a semiconductor device manufacturing method according to a first modification example of the first embodiment. FIGS. 13A and 13B are schematic cross-sectional views.

The semiconductor device manufacturing method according to the first modification example of the first embodiment is different from the semiconductor device manufacturing method according to the first embodiment in that the silicon layer formed on the insulating film is not removed.

The semiconductor device manufacturing method according to the first modification example of the first embodiment is the same as the semiconductor device manufacturing method according to the first embodiment until the polycrystalline silicon layer 16 is formed on the surface of the support substrate 10 (FIG. 13A).

Then, the polycrystalline silicon layer 16 inside the insulating film 12 is made porous using an anodization method without removing the polycrystalline silicon layer 16 formed on the insulating film 12 (FIG. 13B). By making the polycrystalline silicon layer 16 porous, the porous silicon layer 18 is formed inside the insulating film 12.

No current flows through the polycrystalline silicon layer 16 on the insulating film 12 due to the presence of the insulating film 12 during anodization. Therefore, the polycrystalline silicon layer 16 on the insulating film 12 is not made porous.

Then, a three-dimensional NAND flash memory is manufactured by using a method similar to the semiconductor device manufacturing method according to the first embodiment. In addition, the surface may be made flat using, for example, a CMP method before forming the memory layer 30 after the anodization.

### Second Modification Example

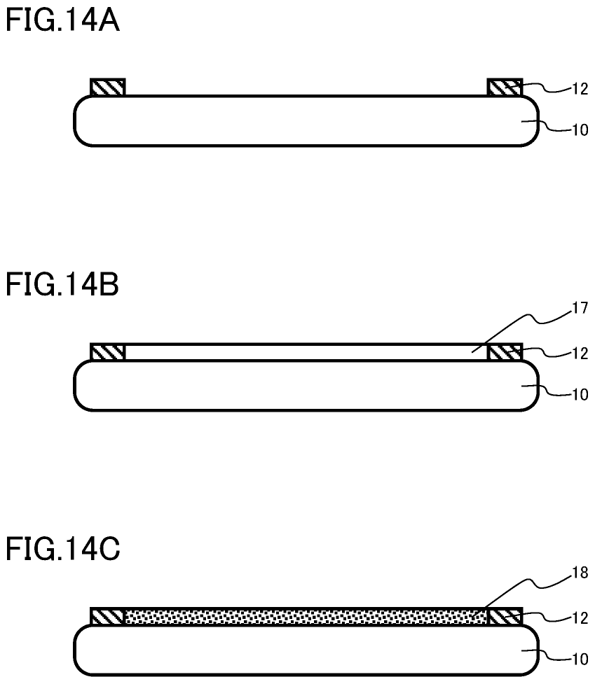

FIGS. 14A, 14B, and 14C are explanatory diagrams of a semiconductor device manufacturing method according to a second modification example of the first embodiment. FIGS. 14A, 14B, and 14C are schematic cross-sectional views.

The semiconductor device manufacturing method according to the second modification example of the first embodiment is different from the semiconductor device manufacturing method according to the first embodiment in that the silicon layer is a single crystal silicon layer formed by using an epitaxial growth method.

The semiconductor device manufacturing method according to the second modification example of the first embodiment is the same as the semiconductor device manufacturing method according to the first embodiment until the annular insulating film 12 is formed on the outer peripheral portion of the support substrate 10 (FIG. 14A).

Then, a single crystal silicon layer 17 is formed on the surface of the support substrate 10 (FIG. 14B). The single crystal silicon layer 17 is an example of a silicon layer. The single crystal silicon layer 17 is formed inside insulating film 12 so as to be in contact with the surface of the support substrate 10.

The single crystal silicon layer 17 is formed by using an epitaxial growth method. The thickness of the single crystal silicon layer 17 is, for example, equal to or more than 100 nm and equal to or less than 10 μm.

Then, the single crystal silicon layer 17 inside the insulating film 12 is made porous using an anodization method (FIG. 14C). By making the single crystal silicon layer 17 porous, the porous silicon layer 18 is formed inside the insulating film 12.

Then, a three-dimensional NAND flash memory is manufactured by using a method similar to the semiconductor device manufacturing method according to the first embodiment.

In the embodiment, the case of patterning the insulating film 12 using a photoresist has been described as an example. However, it is also possible to form the insulating film 12 using a film forming device for selectively forming an insulating film only on the outer peripheral portion of the support substrate 10, for example.

As described above, in the semiconductor device manufacturing methods according to the first embodiment and its modification examples, the position of the outer peripheral end of the porous silicon layer is stabilized. Therefore, when manufacturing a semiconductor device by bonding two substrates together, a stable manufacturing process can be realized.

### Second Embodiment

A semiconductor device manufacturing method according to a second embodiment includes: preparing a first substrate, a surface of an outer peripheral portion of the first substrate being an insulating film and a surface disposed inside the outer peripheral portion being a silicon layer; and forming a porous silicon layer by making the silicon layer inside the insulating film porous using an anodization method. The semiconductor device manufacturing method according to the second embodiment is different from the semiconductor device manufacturing method according to the first embodiment in that a silicon layer is not formed after forming an insulating film on the outer peripheral portion of the surface of a first substrate. Hereinafter, the description of a part of the content common to the semiconductor device manufacturing method according to the first embodiment may be omitted.

The semiconductor device manufacturing method according to the second embodiment is a method for manufacturing a semiconductor device by bonding two substrates together. The semiconductor device is, for example, a semiconductor memory. The semiconductor memory is, for example, a three-dimensional NAND flash memory in which memory cells are arranged in a three-dimensional manner.

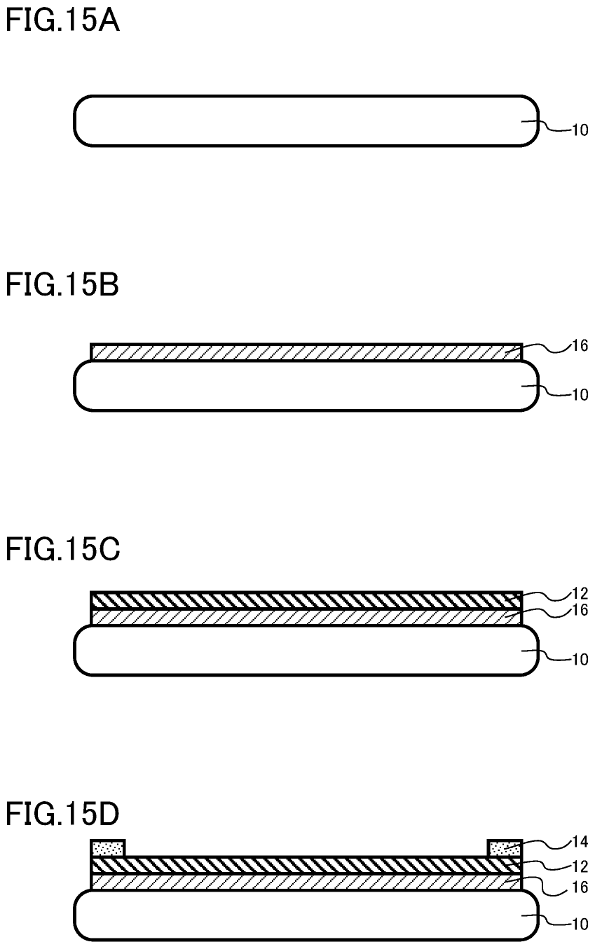

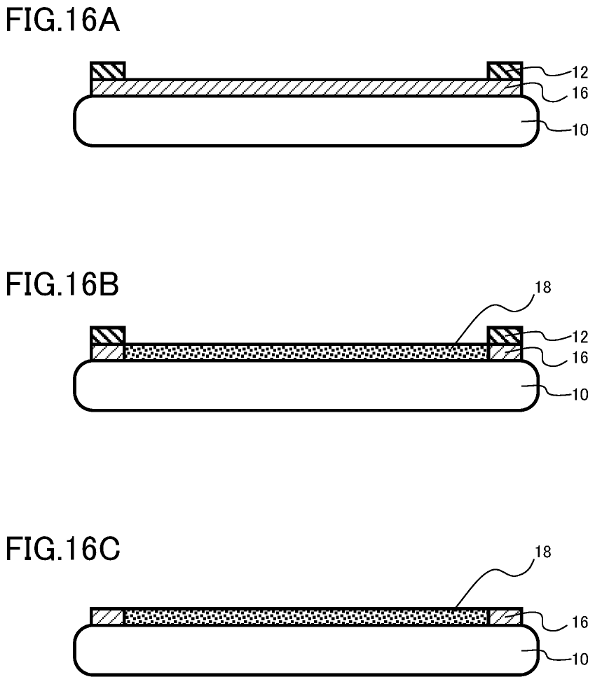

FIGS. 15A, 15B, 15C, 15D, 16A, and 16B are explanatory diagrams of the semiconductor device manufacturing method according to the second embodiment.

FIGS. 15A, 15B, 15C, 15D, 16A, and 16B are schematic cross-sectional views.

First, the support substrate 10 is prepared (FIG. 15A).

The support substrate 10 is a conductor. The support substrate 10 is, for example, a semiconductor. The support substrate 10 is, for example, a single crystal silicon. The support substrate 10 is, for example, a silicon substrate. The support substrate 10 is, for example, a silicon wafer. The support substrate 10 contains boron (B) as a p-type impurity, for example. The support substrate 10 is a p-type silicon wafer.

The diameter of the support substrate 10 is, for example, equal to or more than 150 mm and equal to or less than 300 mm.

Then, the polycrystalline silicon layer 16 is formed on the surface of the support substrate 10 (FIG. 15B). The polycrystalline silicon layer 16 is an example of a silicon layer. The support substrate 10 on which the polycrystalline silicon layer 16 is formed is an example of the first substrate.

The polycrystalline silicon layer 16 is formed by using, for example, a CVD method. The thickness of the polycrystalline silicon layer 16 is, for example, equal to or more than 100 nm and equal to or less than 10 μm. Then, the insulating film 12 is formed on the surface of the polycrystalline silicon layer 16 (FIG. 15C). The insulating film 12 is formed by using, for example, a chemical vapor deposition method (CVD method).

The insulating film 12 is, for example, an oxide, a nitride, an oxynitride, or a carbide. The insulating film 12 is, for example, a silicon oxide, a silicon nitride, or a nitrogen-doped silicon carbide.

The thickness of the insulating film 12 is, for example, equal to or more than 100 nm and equal to or less than 10 μm.

Then, a photoresist film 14 is formed so as to cover the insulating film 12 on the outer peripheral portion of the support substrate 10 (FIG. 15D). For example, the photoresist film 14 is formed by patterning using a photolithography method.

For example, when a positive resist is used as the photoresist film 14, the photoresist film 14 is applied to the surface of the support substrate 10, and then sensitizing the photoresist film 14 by exposing the central portion of the support substrate 10 to light, thereby removing the photoresist film 14 on the central portion of the support substrate 10.

In addition, for example, when a negative resist is used as the photoresist film 14, the photoresist film 14 is applied to the surface of the support substrate 10, and then sensitizing the photoresist film 14 by exposing the outer peripheral portion of the support substrate 10 to light, thereby removing the photoresist film 14 on the central portion of the support substrate 10.

Then, using the patterned photoresist film 14 as a mask, the insulating film 12 on the central portion of the support substrate 10 is removed. The insulating film 12 is removed by using, for example, a wet etching method. Then, the photoresist film 14 is removed (FIG. 16A). The annular insulating film 12 is formed on the outer peripheral portion of the support substrate 10. The surface of the outer peripheral portion of the support substrate 10 is the insulating film 12, and the surface disposed inside the outer peripheral portion is the polycrystalline silicon layer 16.

Then, the polycrystalline silicon layer 16 inside the insulating film 12 is made porous using an anodization method (FIG. 16B). By making the polycrystalline silicon layer 16 porous, the porous silicon layer 18 is formed inside the insulating film 12. The porous silicon layer 18 has a void inside.

No current flows through the polycrystalline silicon layer 16 below the insulating film 12 due to the presence of the insulating film 12 on the polycrystalline silicon layer 16 during anodization. Therefore, the polycrystalline silicon layer 16 below the insulating film 12 is not made porous.

Then, the insulating film 12 on the polycrystalline silicon layer 16 is removed (FIG. 16C). The insulating film 12 is removed by using, for example, a wet etching method.

Then, a three-dimensional NAND flash memory is manufactured by using a method similar to the semiconductor device manufacturing method according to the first embodiment.

In the semiconductor device manufacturing method according to the second embodiment, as in the first embodiment, since the position of the outer peripheral end of the porous silicon layer 18 is stabilized, it is possible to stabilize the manufacturing process for a semiconductor device manufactured by bonding the support substrate 10 and the semiconductor substrate 40 together.

### Modification Examples

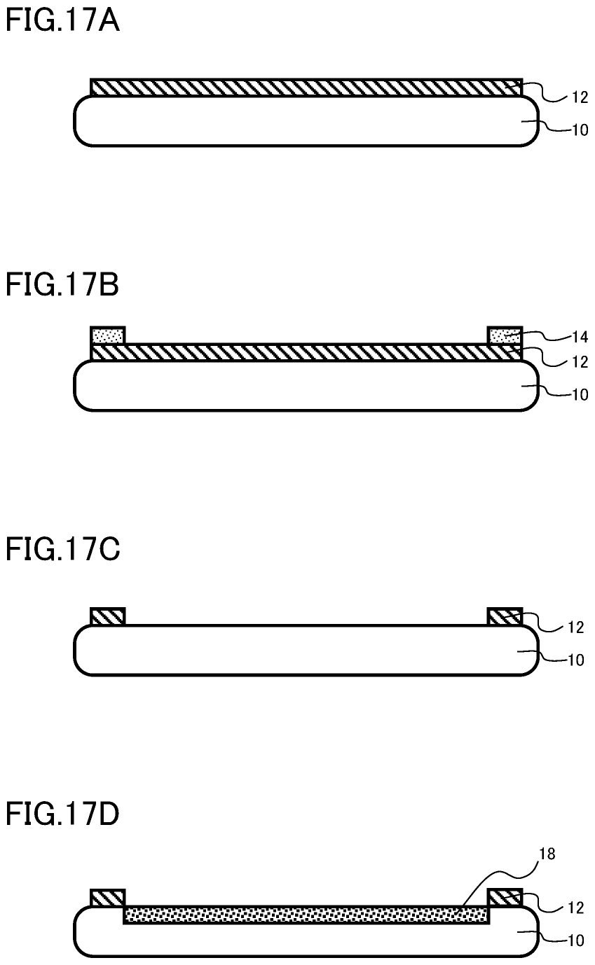

FIGS. 17A, 17B, 17C, and 17D are explanatory diagrams of a semiconductor device manufacturing method according to a modification example of the second embodiment. FIGS. 17A, 17B, 17C, and 17D are schematic cross-sectional views.

The semiconductor device manufacturing method according to the modification example of the second embodiment is different from the semiconductor device manufacturing method according to the second embodiment in that the silicon layer is a surface layer portion of the silicon substrate.

The insulating film 12 is formed on the surface of the support substrate 10 (FIG. 17A). The insulating film 12 is formed by using, for example, a chemical vapor deposition method (CVD method). The support substrate 10 is a silicon substrate. The support substrate 10 is an example of the first substrate. The surface layer portion of the silicon substrate is an example of the silicon layer.

The insulating film 12 is, for example, an oxide, a nitride, an oxynitride, or a carbide. The insulating film 12 is, for example, a silicon oxide, a silicon nitride, or a nitrogen-doped silicon carbide.

The thickness of the insulating film 12 is, for example, equal to or more than 100 nm and equal to or less than 10 μm.

Then, a photoresist film 14 is formed so as to cover the insulating film 12 on the outer peripheral portion of the support substrate 10 (FIG. 17B). For example, the photoresist film 14 is formed by patterning using a photolithography method.

Then, using the patterned photoresist film 14 as a mask, the insulating film 12 on the central portion of the support substrate 10 is removed. The insulating film 12 is removed by using, for example, a wet etching method.

Then, the photoresist film 14 is removed (FIG. 17C). The annular insulating film 12 is formed on the outer peripheral portion of the support substrate 10.

Then, the silicon layer at the surface layer portion of the silicon substrate inside the insulating film 12 is made porous using an anodization method (FIG. 17D). By making the silicon substrate porous, the porous silicon layer 18 is formed inside the insulating film 12. The porous silicon layer 18 has a void inside.

No current flows through the silicon substrate below the insulating film 12 due to the presence of the insulating film 12 on the silicon substrate during anodization. Therefore, the silicon substrate below the insulating film 12 is not made porous.

Then, the insulating film 12 on the support substrate 10, which is a silicon substrate, is removed. The insulating film 12 is removed by using, for example, a wet etching method.

Then, a three-dimensional NAND flash memory is manufactured by using a method similar to the semiconductor device manufacturing method according to the first embodiment.

In the semiconductor device manufacturing methods according to the second embodiment and its modification example, the position of the outer peripheral end of the porous silicon layer is stabilized. Therefore, when manufacturing a semiconductor device by bonding two substrates together, a stable manufacturing process can be realized.

### Third Embodiment

A semiconductor device manufacturing method according to a third embodiment includes: preparing a first substrate, at least a surface of the first substrate being a silicon layer; and forming a porous silicon layer by making the silicon layer porous using an anodization method, the porous silicon layer having a first porous region having a first porosity and a second porous region provided in a direction along the surface with respect to the first porous region and having a second porosity higher than the first porosity. In addition, in the semiconductor device manufacturing method according to the third embodiment, before forming the porous silicon layer, a first region and a second region having an impurity concentration higher than that of the first region are formed by implanting impurities into the silicon layer using an ion implantation method. When making the silicon layer porous, the first region becomes the first porous region and the second region becomes the second porous region.

The semiconductor device manufacturing method according to the third embodiment is different from the semiconductor device manufacturing method according to the first embodiment in that the process of forming a porous silicon layer on the first substrate is different. Hereinafter, the description of the content overlapping the method for manufacturing the semiconductor device according to the first embodiment may be omitted.

The semiconductor device manufacturing method according to the third embodiment is a method for manufacturing a semiconductor device by bonding two substrates together. The semiconductor device is, for example, a semiconductor memory. The semiconductor memory is, for example, a three-dimensional NAND flash memory in which memory cells are arranged in a three-dimensional manner.

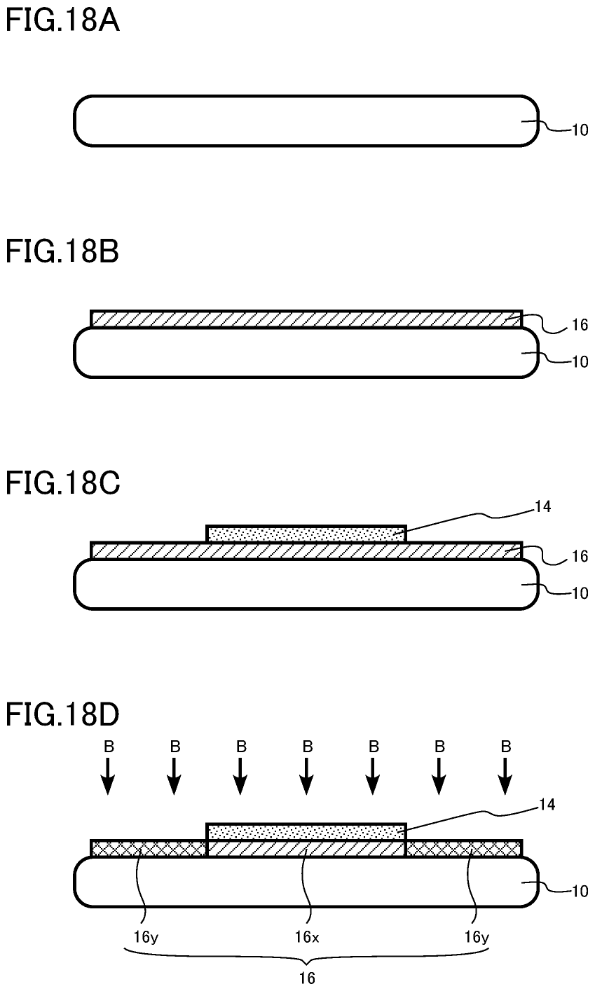

FIGS. 18A, 18B, 18C, 18D, 19A, 19B, 20A, and 20B are explanatory diagrams of the semiconductor device manufacturing method according to the third embodiment.

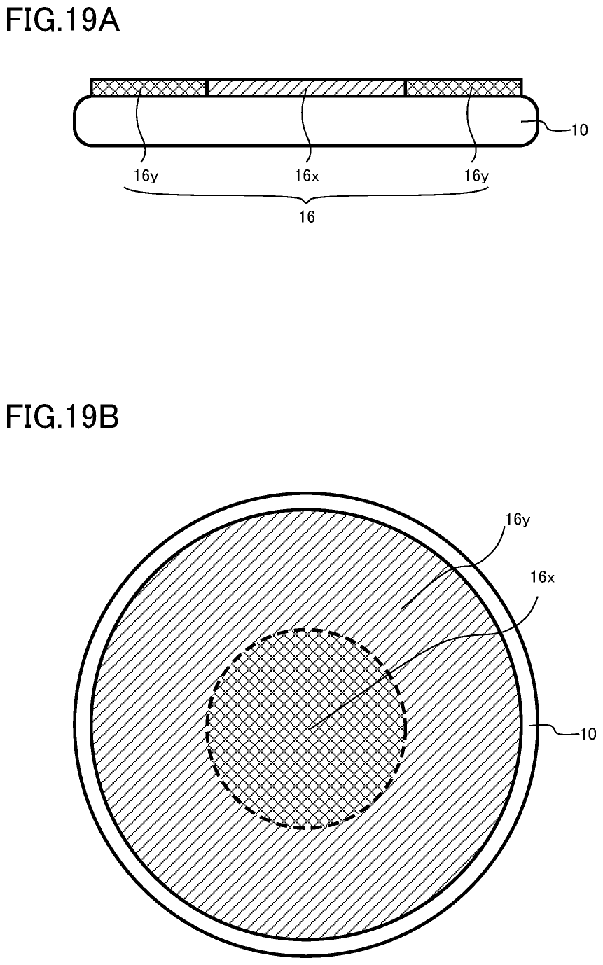

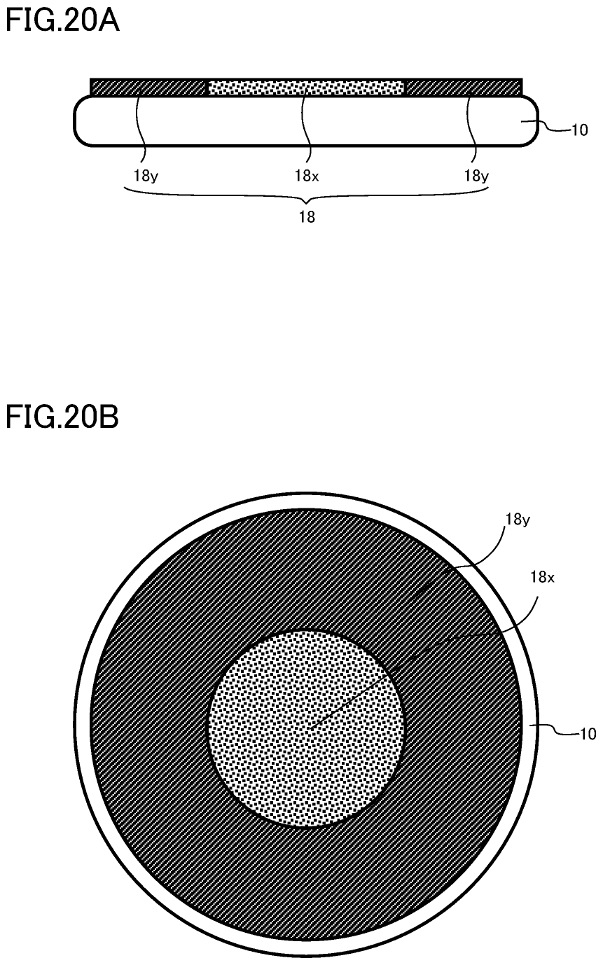

FIGS. 18A, 18B, 18C, 18D, 19A, and 20A are schematic cross-sectional views. FIGS. 19B and 20B are schematic top views.

First, the support substrate 10 is prepared (FIG. 18A).

The support substrate 10 is a conductor. The support substrate 10 is, for example, a semiconductor. The support substrate 10 is, for example, a single crystal silicon. The support substrate 10 is, for example, a silicon substrate. The support substrate 10 is, for example, a p-type silicon substrate containing boron (B) as a p-type impurity.

The diameter of the support substrate 10 is, for example, equal to or more than 150 mm and equal to or less than 300 mm.

Then, the polycrystalline silicon layer 16 is formed on the surface of the support substrate 10 (FIG. 18B). The polycrystalline silicon layer 16 is an example of a silicon layer. The support substrate 10 on which the polycrystalline silicon layer 16 is formed is an example of the first substrate.

The polycrystalline silicon layer 16 is formed by using, for example, a CVD method. The thickness of the polycrystalline silicon layer 16 is, for example, equal to or more than 100 nm and equal to or less than 10 μm.

Then, the photoresist film 14 is formed so as to cover the central portion of the support substrate 10 (FIG. 18C). For example, the photoresist film 14 is formed by patterning using a photolithography method.

Then, using the patterned photoresist film 14 as a mask, boron (B) ions are implanted into the outer peripheral portion of the support substrate 10 by using an ion implantation method (FIG. 18D). Boron (B) is an example of an impurity.

Then, the photoresist film 14 is removed (FIG. 19A). As shown in FIGS. 19A and 19B, a low impurity concentration region 16x is formed in the central portion of the polycrystalline silicon layer 16, and a high impurity concentration region 16y is formed in the outer peripheral portion of the polycrystalline silicon layer 16. The low impurity concentration region 16x is an example of the first region. In addition, the high impurity concentration region 16y is an example of the second region.

The impurity concentration of conductive impurities in the high impurity concentration region 16y is higher than the impurity concentration of conductive impurities in the low impurity concentration region 16x. For example, the concentration of boron (B) in the high impurity concentration region 16y is higher than the concentration of boron (B) in the low impurity concentration region 16x.

The resistivity of the high impurity concentration region 16y is lower than the resistivity of the low impurity concentration region 16x. The resistivity of the high impurity concentration region 16y is equal to or more than 1/1000 and equal to or less than ⅕ of the resistivity of the low impurity concentration region 16x. The resistivity of the high impurity concentration region 16y is, for example, equal to or more than 0.001 Ω·cm and equal to or less than 0.09 Ω·cm. In addition, the resistivity of the low impurity concentration region 16x is, for example, equal to or more than 0.01 Ω·cm and equal to or less than 0.1 Ω·cm.

In addition, when the concentration of boron (B) in the low impurity concentration region 16x is less than the desired concentration, for example, after removing the photoresist film 14, ion implantation may be performed again in the central portion and the outer peripheral portion of the polycrystalline silicon layer 16.

Then, the polycrystalline silicon layer 16 is made porous using an anodization method (FIGS. 20A and 20B). In addition, the anodization method used is the same as the anodization method used in the semiconductor device manufacturing method according to the first embodiment.

By making the polycrystalline silicon layer 16 porous, the porous silicon layer 18 is formed. The porous silicon layer 18 has a void inside.

The central portion of the porous silicon layer 18 becomes a low porous region 18x. In addition, the outer peripheral portion of the porous silicon layer 18 becomes a high porous region 18y. The low porous region 18x is an example of the first porous region. The high porous region 18y is an example of the second porous region.

The high porous region 18y surrounds the low porous region 18x. The high porous region 18y is provided in a direction along the surface of the polycrystalline silicon layer 16 with respect to the low porous region 18x.

When forming the porous silicon layer 18 using an anodization method, the low impurity concentration region 16x becomes the low porous region 18x. In addition, the high impurity concentration region 16y becomes the high porous region 18y.

The high porous region 18y has a first porosity. In addition, the low porous region 18x has a second porosity. The first porosity is higher than the second porosity.

In addition, “porosity” is the ratio of the volume of the void in the porous silicon layer 18 to the total volume. For example, as the “porosity” of the porous silicon layer 18 increases, the volume ratio of silicon in the porous silicon layer 18 decreases. For example, the relationship of the magnitude of the porosity can be determined by acquiring an image of a cross section of the porous silicon layer 18 using a SEM and comparing the area ratio of the void in the image.

When forming the porous silicon layer 18 using an anodization method, a larger amount of current flows through the high impurity concentration region 16y with a low resistance than through the low impurity concentration region 16x with a high resistance. Therefore, the high impurity concentration region 16y becomes more porous, and the high porous region 18y with a high porosity is obtained.

After the porous silicon layer 18 is formed, a three-dimensional NAND flash memory is manufactured by using a method similar to the semiconductor device manufacturing method according to the first embodiment.

Next, the function and effect of the semiconductor device manufacturing method according to the third embodiment will be explained.

As described with reference to FIG. 9 in the semiconductor device manufacturing method according to the first embodiment, also in the semiconductor device manufacturing method according to the third embodiment, the support substrate 10 and the semiconductor substrate 40 are separated from each other with the porous silicon layer 18 as a boundary. For example, by pressing a wedge-shaped jig from the side toward the boundary between the memory layer 30 and the wiring layer 40b and/or spraying a water jet, the porous silicon layer 18 is mechanically divided with the boundary between the memory layer 30 and the wiring layer 40b as a starting point so that the support substrate 10 and the semiconductor substrate 40 are separated from each other.

In order to divide the porous silicon layer 18 when separating the support substrate 10 and the semiconductor substrate 40 from each other, the mechanical strength of the porous silicon layer 18 is required to be lower than that of other portions. For example, the mechanical strength of the porous silicon layer 18 is required to be lower than the mechanical strength of the bonding surface between the support substrate 10 and the semiconductor substrate 40.

On the other hand, after the porous silicon layer 18 is formed on the support substrate 10, the memory layer 30 is formed on the porous silicon layer 18. When forming the memory layer 30, film formation or heat treatment is performed. During the film formation or heat treatment, stress is applied to the porous silicon layer 18. Therefore, the porous silicon layer 18 is required to have a mechanical strength to the extent that the porous silicon layer 18 is not broken by the stress applied when forming the memory layer 30.

If the mechanical strength of the porous silicon layer 18 is too high, when separating the support substrate 10 and the semiconductor substrate 40 from each other, for example, peeling may occur at the bonding surface of the support substrate 10 and the semiconductor substrate 40. Therefore, it is not possible to continue manufacturing the product. In addition, if the mechanical strength of the porous silicon layer 18 is too low, the porous silicon layer 18 is broken during the formation of the memory layer 30. Therefore, it is not possible to continue manufacturing the product.

In the semiconductor device manufacturing method according to the third embodiment, the low porous region 18x is provided in the central portion of the support substrate 10, and the high porous region 18y is provided in the outer peripheral portion of the support substrate 10. The porosity of the high porous region 18y is higher than the porosity of the low porous region 18x. The mechanical strength of the high porous region 18y with a high porosity is lower than that of the low porous region 18x with a low porosity.

For example, a case is considered in which when separating the support substrate 10 and the semiconductor substrate 40 from each other, the porous silicon layer 18 is divided by pressing a wedge-shaped jig from the side toward the porous silicon layer 18. In the semiconductor device manufacturing method according to the third embodiment, since the high porous region 18y with a low mechanical strength is present in the outer peripheral portion of the support substrate 10, the support substrate 10 and the semiconductor substrate 40 are easily divided.

On the other hand, due to the presence of the low porous region 18x with a high mechanical strength in the central portion of the support substrate 10, the mechanical strength of the porous silicon layer 18 is maintained. Therefore, it is possible to suppress the breakage of the porous silicon layer 18 during the formation of the memory layer 30.

According to the semiconductor device manufacturing method according to the third embodiment, the in-plane distribution of the mechanical strength of the porous silicon layer 18 is optimized by controlling the in-plane distribution of porosity in the porous silicon layer 18. Therefore, according to the semiconductor device manufacturing method according to the third embodiment, it is possible to stabilize the manufacturing process for a semiconductor device manufactured by bonding the support substrate 10 and the semiconductor substrate 40 together.

### First Modification Example

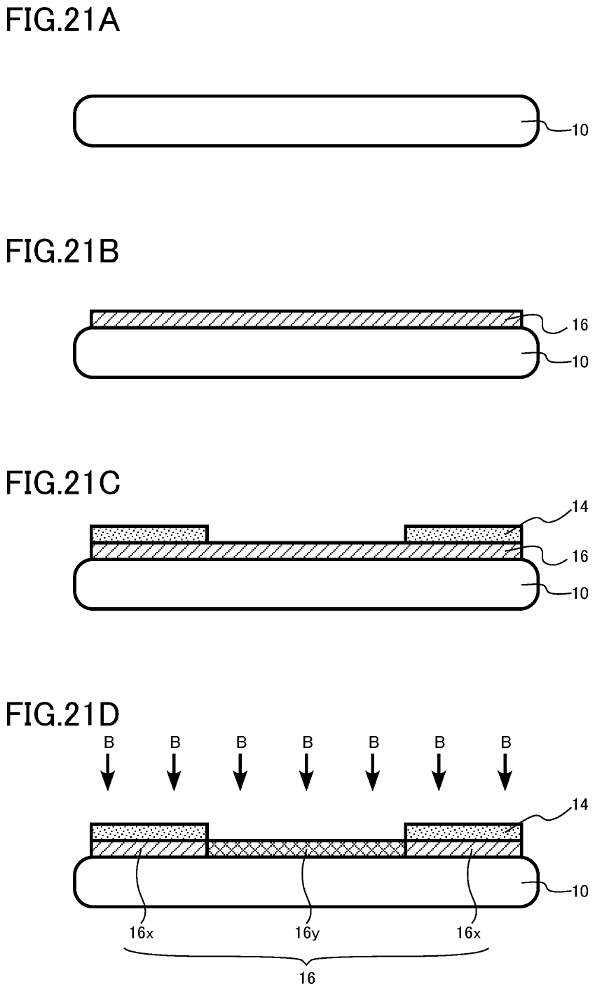

FIGS. 21A, 21B, 21C, 21D, 22A, 22B, 23A, and 23B are explanatory diagrams of a semiconductor device manufacturing method according to a first modification example of the third embodiment.

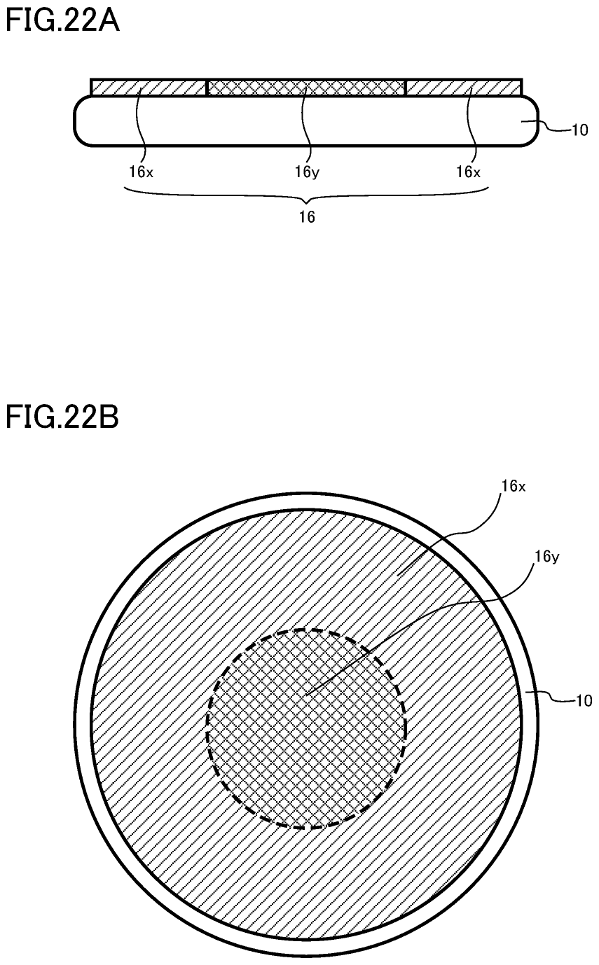

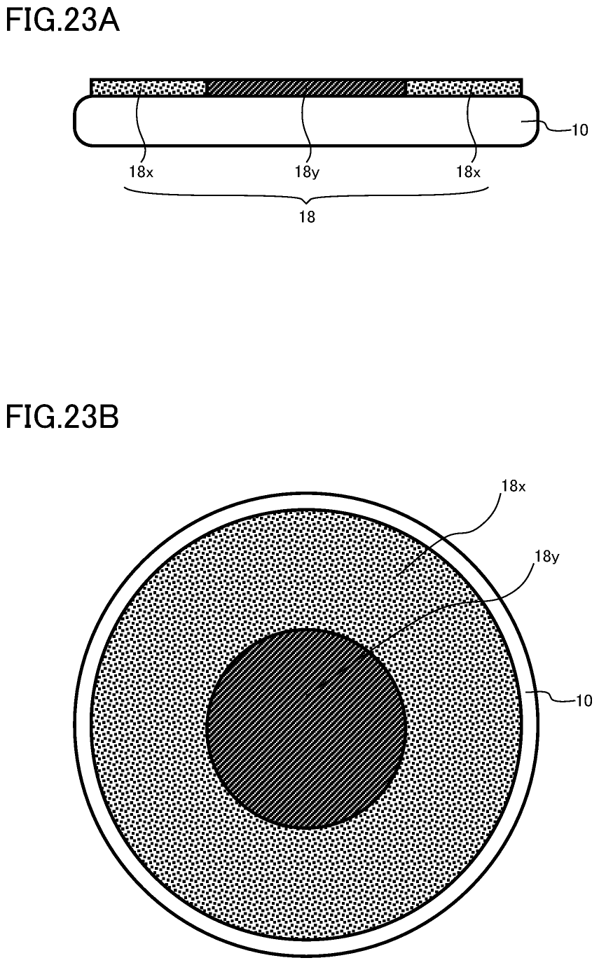

FIGS. 21A, 21B, 21C, 21D, 22A, and 23A are schematic cross-sectional views. FIGS. 22B and 23B are schematic top views.

The semiconductor device manufacturing method according to the first modification example of the third embodiment is different from the semiconductor device manufacturing method according to the third embodiment in that the first porous region surrounds the second porous region. For example, the semiconductor device manufacturing method according to the first modification example of the third embodiment is different from the semiconductor device manufacturing method according to the third embodiment in that the low porous region 18x surrounds the high porous region 18y.

First, the support substrate 10 is prepared (FIG. 21A).

Then, the polycrystalline silicon layer 16 is formed on the surface of the support substrate 10 (FIG. 21B). The polycrystalline silicon layer 16 is an example of a silicon layer. The support substrate 10 on which the polycrystalline silicon layer 16 is formed is an example of the first substrate.

Then, the photoresist film 14 is formed so as to cover the outer peripheral portion of the support substrate 10 (FIG. 21C). For example, the photoresist film 14 is formed by patterning using a photolithography method.

Then, using the patterned photoresist film 14 as a mask, boron (B) ions are implanted into the central portion of the support substrate 10 by using an ion implantation method (FIG. 21D). Boron (B) is an example of an impurity.

Then, the photoresist film 14 is removed (FIG. 22A). As shown in FIGS. 22A and 22B, the low impurity concentration region 16x is formed in the outer peripheral portion of the polycrystalline silicon layer 16, and the high impurity concentration region 16y is formed in the central portion of the polycrystalline silicon layer 16. The low impurity concentration region 16x is an example of the first region. In addition, the high impurity concentration region 16y is an example of the second region.

In addition, when the concentration of boron (B) in the low impurity concentration region 16x is less than the desired concentration, for example, after removing the photoresist film 14, ion implantation may be performed again in the central portion and the outer peripheral portion of the polycrystalline silicon layer 16.

The impurity concentration of conductive impurities in the high impurity concentration region 16y is higher than the impurity concentration of conductive impurities in the low impurity concentration region 16x. For example, the concentration of boron (B) in the high impurity concentration region 16y is higher than the concentration of boron (B) in the low impurity concentration region 16x.

The resistivity of the high impurity concentration region 16y is lower than the resistivity of the low impurity concentration region 16x.

Then, the polycrystalline silicon layer 16 is made porous using an anodization method (FIGS. 23A and 23B).

By making the polycrystalline silicon layer 16 porous, the porous silicon layer 18 is formed. Porous silicon layer 18 has a void inside.

The central portion of the porous silicon layer 18 becomes the high porous region 18y. In addition, the outer peripheral portion of the porous silicon layer 18 becomes the low porous region 18x. The low porous region 18x is an example of the first porous region. The high porous region 18y is an example of the second porous region. The low porous region 18x surrounds the high porous region 18y. The high porous region 18y is provided in a direction along the surface of the polycrystalline silicon layer 16 with respect to the low porous region 18x.

When forming the porous silicon layer 18 using an anodization method, the low impurity concentration region 16x becomes the low porous region 18x. In addition, the high impurity concentration region 16y becomes the high porous region 18y.

The high porous region 18y has a first porosity. In addition, the low porous region 18x has a second porosity. The first porosity is higher than the second porosity.

After the porous silicon layer 18 is formed, a three-dimensional NAND flash memory is manufactured by using a method similar to the semiconductor device manufacturing method according to the first embodiment. In the semiconductor device manufacturing method according to the first modification example of the third embodiment, the high porous region 18y is provided in the central portion of the support substrate 10, and the low porous region 18x is provided in the outer peripheral portion of the support substrate 10. The porosity of the high porous region 18y is higher than the porosity of the low porous region 18x. The mechanical strength of the high porous region 18y with a high porosity is lower than that of the low porous region 18x with a low porosity.

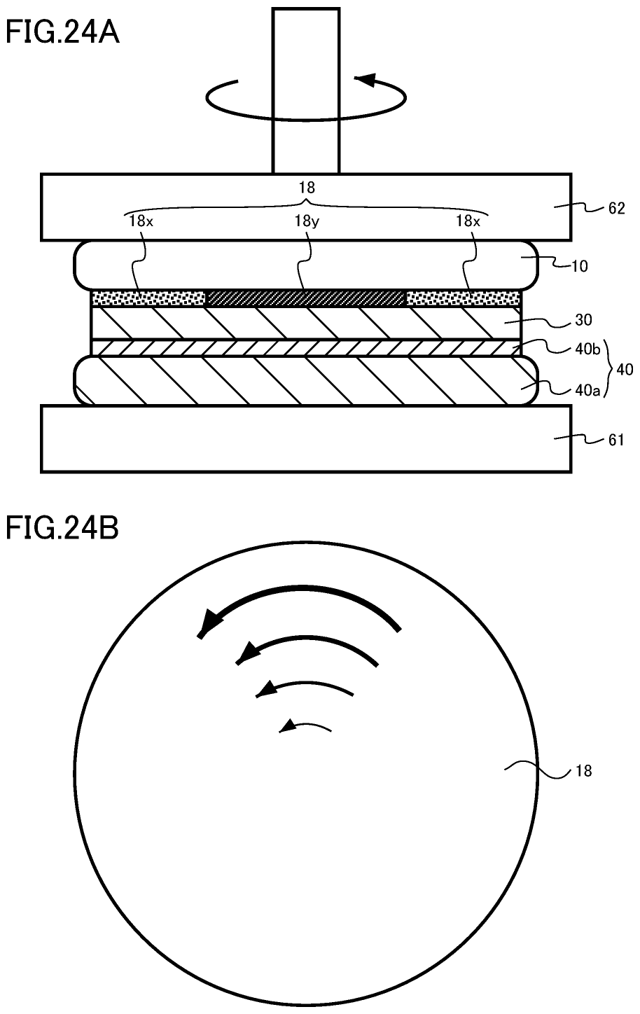

FIGS. 24A and 24B are explanatory diagrams of the semiconductor device manufacturing method according to the first modification example of the third embodiment. FIGS. 24A and 24B show an example of a method for separating the support substrate 10 and the semiconductor substrate 40 from each other.

As shown in FIG. 24A, when separating the support substrate 10 and the semiconductor substrate 40 from each other, the semiconductor substrate 40 is fixed to a first support part 61. For example, the semiconductor substrate 40 is fixed to the first support part 61 by vacuum suction. In addition, the support substrate 10 is fixed to a second support part 62. For example, the support substrate 10 is fixed to the second support part 62 by vacuum suction.

Then, as shown in FIG. 24A, by rotating the second support part 62 with respect to the first support part 61, shear stress is applied to the porous silicon layer 18 so that the porous silicon layer 18 is divided.

FIG. 24B is a schematic diagram showing the in-plane distribution of the magnitude of shear stress applied to the porous silicon layer 18. As shown in FIG. 24B, the shear stress applied to the porous silicon layer 18 increases in the outer peripheral portion of the porous silicon layer 18. In other words, the shear stress applied to the porous silicon layer 18 decreases in the central portion of the porous silicon layer 18.

In the semiconductor device manufacturing method according to the first modification example of the third embodiment, since the high porous region 18y with a low mechanical strength is present in the central portion of the support substrate 10, the support substrate 10 and the semiconductor substrate 40 are easily divided even when the shear stress applied to the porous silicon layer 18 on the central portion of the support substrate 10 is small.

On the other hand, due to the presence of the low porous region 18x with a high mechanical strength in the outer peripheral portion of the support substrate 10, the mechanical strength of the porous silicon layer 18 is maintained. Therefore, it is possible to suppress the breakage of the porous silicon layer 18 during the formation of the memory layer 30.

### Second Modification Example

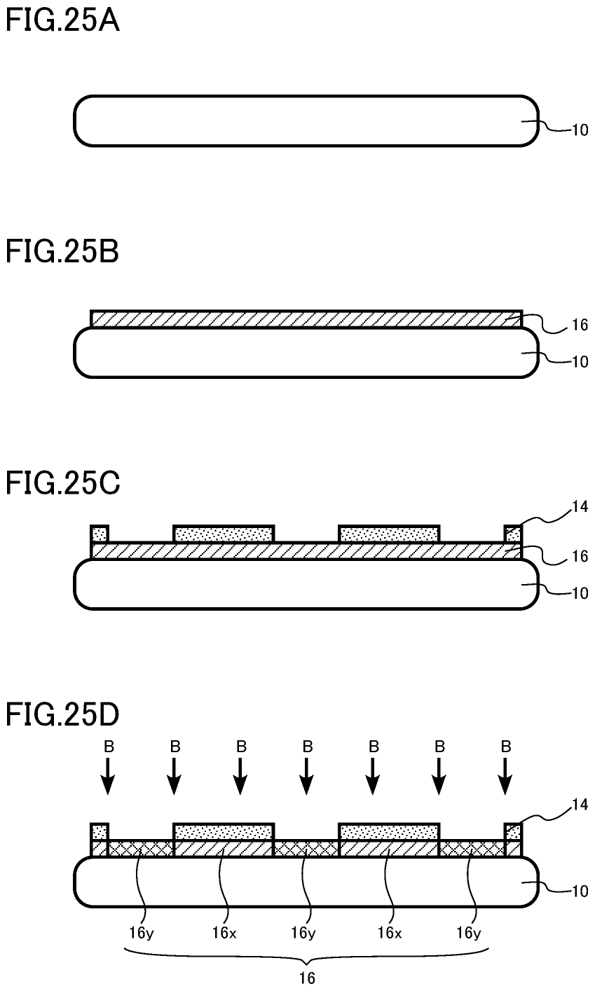

FIGS. 25A, 25B, 25C, 25D, 26A, 26B, 27A, and 27B are explanatory diagrams of a semiconductor device manufacturing method according to a second modification example of the third embodiment.

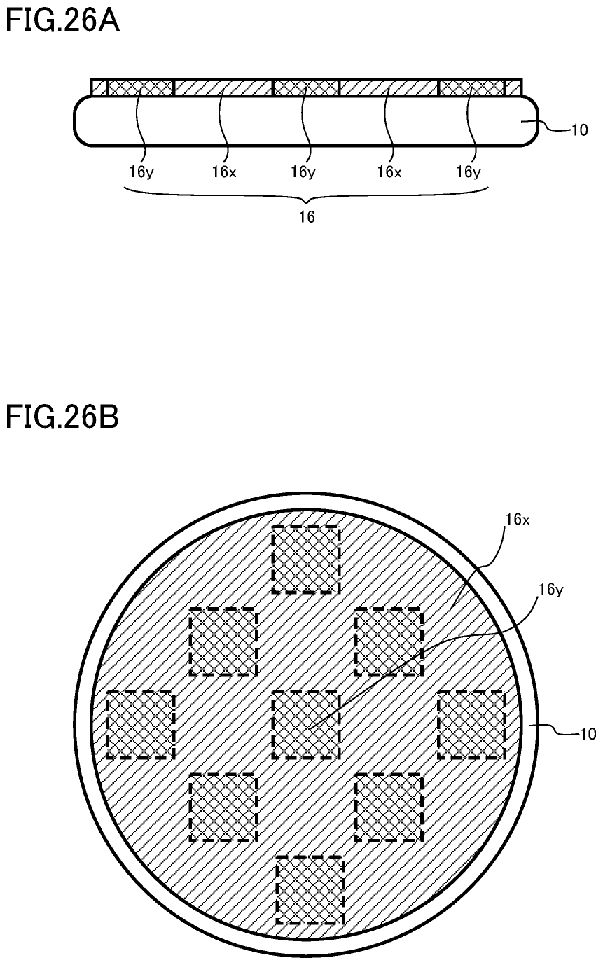

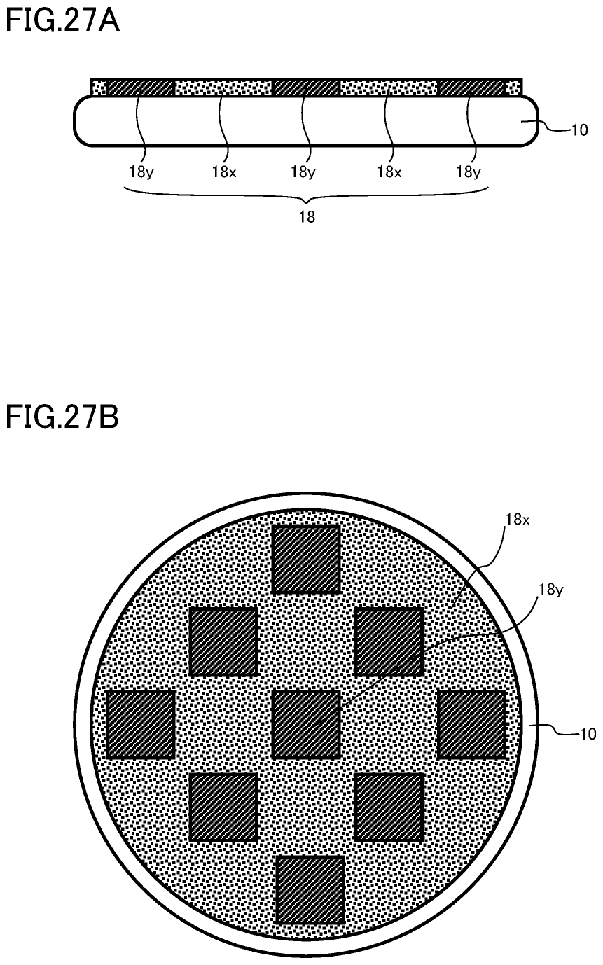

FIGS. 25A, 25B, 25C, 25D, 26A, and 27A are schematic cross-sectional views. FIGS. 26B and 27B are schematic top views.

The semiconductor device manufacturing method according to the second modification example of the third embodiment is different from the semiconductor device manufacturing method according to the third embodiment in that a first porous region and a second porous region have a checkerboard pattern. For example, the semiconductor device manufacturing method according to the second modification example of the third embodiment is different from the semiconductor device manufacturing method according to the third embodiment in that the low porous region 18x and the high porous region 18y have a checkerboard pattern.

First, the support substrate 10 is prepared (FIG. 25A).

Then, the polycrystalline silicon layer 16 is formed on the surface of the support substrate 10 (FIG. 25B). The polycrystalline silicon layer 16 is an example of a silicon layer. The support substrate 10 on which the polycrystalline silicon layer 16 is formed is an example of the first substrate.

Then, the photoresist film 14 is formed on the support substrate 10 (FIG. 25C). For example, the photoresist film 14 is formed by patterning using a photolithography method. The photoresist film 14 has a checkerboard pattern.

Then, using the patterned photoresist film 14 as a mask, boron (B) ions are implanted into the support substrate 10 by using an ion implantation method (FIG. 25D). Boron (B) is an example of an impurity.

Then, the photoresist film 14 is removed (FIG. 26A). As shown in FIGS. 26A and 26B, the low impurity concentration region 16x and the high impurity concentration region 16y are formed in the polycrystalline silicon layer 16. The low impurity concentration region 16x and the high impurity concentration region 16y have a checkerboard pattern. The low impurity concentration region 16x is an example of the first region. In addition, the high impurity concentration region 16y is an example of the second region.

In addition, when the concentration of boron (B) in the low impurity concentration region 16x is less than the desired concentration, for example, after removing the photoresist film 14, ion implantation may be performed again in the central portion and the outer peripheral portion of the polycrystalline silicon layer 16.

The impurity concentration of conductive impurities in the high impurity concentration region 16y is higher than the impurity concentration of conductive impurities in the low impurity concentration region 16x. For example, the concentration of boron (B) in the high impurity concentration region 16y is higher than the concentration of boron (B) in the low impurity concentration region 16x.

The resistivity of the high impurity concentration region 16y is lower than the resistivity of the low impurity concentration region 16x.

Then, the polycrystalline silicon layer 16 is made porous using an anodization method (FIGS. 27A and 27B).

By making the polycrystalline silicon layer 16 porous, the porous silicon layer 18 is formed. The porous silicon layer 18 has a void inside.

The low porous region 18x and the high porous region 18y having a checkerboard pattern are formed in the porous silicon layer 18. The low porous region 18x is an example of the first porous region. The high porous region 18y is an example of the second porous region. The low porous region 18x surrounds the high porous region 18y. The high porous region 18y is provided in a direction along the surface of the porous silicon layer 18 with respect to the low porous region 18x.

When forming the porous silicon layer 18 using an anodization method, the low impurity concentration region 16x becomes the low porous region 18x. In addition, the high impurity concentration region 16y becomes the high porous region 18y.

The high porous region 18y has a first porosity. In addition, the low porous region 18x has a second porosity. The first porosity is higher than the second porosity.

After the porous silicon layer 18 is formed, a three-dimensional NAND flash memory is manufactured by using a method similar to the semiconductor device manufacturing method according to the first embodiment.

In the semiconductor device manufacturing method according to the second modification example of the third embodiment, the low porous region 18x and the high porous region 18y having a checkerboard pattern are provided in the porous silicon layer 18 of the support substrate 10. The porosity of the high porous region 18y is higher than the porosity of the low porous region 18x. The mechanical strength of the high porous region 18y with a high porosity is lower than that of the low porous region 18x with a low porosity.

In the semiconductor device manufacturing method according to the second modification example of the third embodiment, the high porous region 18y with a low mechanical strength and the low porous region 18x with a low mechanical strength are arranged evenly in the porous silicon layer 18 of the support substrate 10. Therefore, for example, the support substrate 10 and the semiconductor substrate 40 are easily divided, and the breakage of the porous silicon layer 18 during the formation of the memory layer 30 can be suppressed.

In addition, compared with the semiconductor device manufacturing method according to the third embodiment or the semiconductor device manufacturing method according to the first modification example of the third embodiment, the low porous region 18x and the high porous region 18y having different physical properties are arranged evenly. Therefore, for example, the warpage of the support substrate 10 can be suppressed.

In addition, in the third embodiment and its modification examples, boron (B) has been described as an example of the conductive impurity ion-implanted into the silicon layer. However, the conductive impurity is not limited to boron (B). For example, it is also possible to use phosphorus (P) or arsenic (As) as a conductive impurity.

For example, when the support substrate 10 is a p-type silicon substrate, the conductive impurity ion-implanted into the silicon layer is preferably boron (B), which is a p-type conductive impurity. In addition, for example, when the support substrate 10 is an n-type silicon substrate, the conductive impurity ion-implanted into the silicon layer is preferably phosphorus (P) or arsenic (As), which is an n-type conductive impurity.

In the third embodiment and its modification examples, the method of making the polycrystalline silicon layer 16 on the surface of the support substrate 10 porous has been described as an example. However, the support substrate 10 may be a silicon substrate, and a single crystal silicon layer at the surface layer portion of the support substrate 10 may be made porous.

In the third embodiment and its modification examples, a method of performing one ion implantation has been described as an example. However, for example, ion implantation may be performed multiple times with different doses in different regions.

As described above, according to the semiconductor device manufacturing methods according to the third embodiment and its modification examples, the in-plane distribution of the mechanical strength of the porous silicon layer is optimized by controlling the in-plane distribution of porosity in the porous silicon layer. Therefore, when manufacturing a semiconductor device by bonding two substrates together, a stable manufacturing process can be realized.

### Fourth Embodiment

A semiconductor device manufacturing method according to a fourth embodiment is different from the semiconductor device manufacturing method according to the third embodiment in that a first step and a second step are included when forming the porous silicon layer, a first substrate holder for limiting a portion of the silicon layer in contact with an electrolyte to a first region is used in the first step, a second substrate holder for limiting a portion of the silicon layer in contact with an electrolyte to a second region inside the first region is used in the second step, and the second region becomes the second porous region and the first region outside the second region becomes the first porous region.

The semiconductor device manufacturing method according to the fourth embodiment is different from the semiconductor device manufacturing methods according to the first and third embodiments in that the process of forming a porous silicon layer on the first substrate is different. Hereinafter, the description of the content overlapping the semiconductor device manufacturing methods according to the first and third embodiments may be omitted.

The semiconductor device manufacturing method according to the fourth embodiment is a method for manufacturing a semiconductor device by bonding two substrates together. The semiconductor device is, for example, a semiconductor memory. The semiconductor memory is, for example, a three-dimensional NAND flash memory in which memory cells are arranged in a three-dimensional manner.

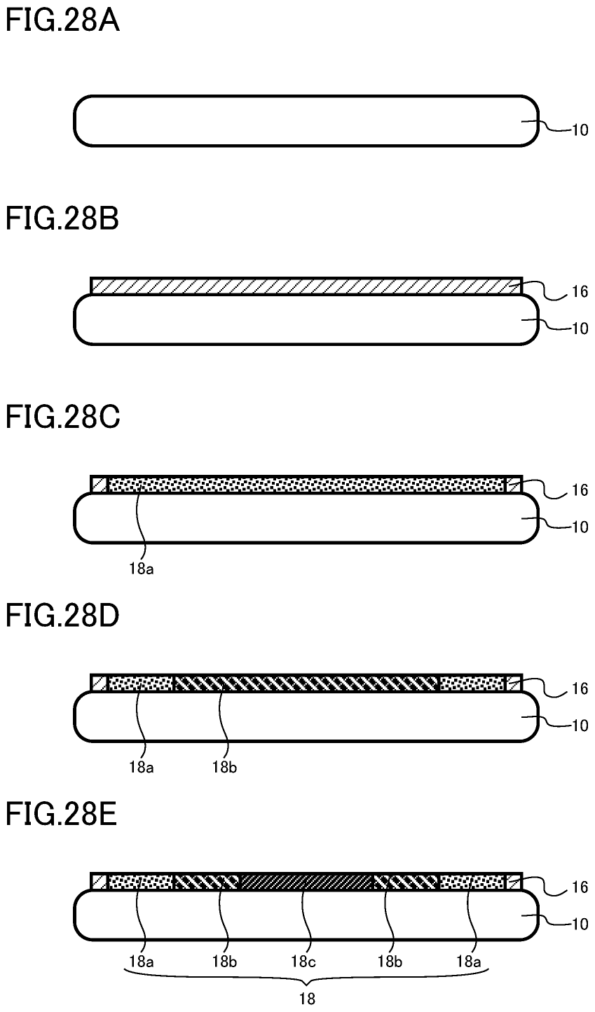

FIGS. 28A, 28B, 28C, 28D, 28E, 29A, 29B, 29C, 30A, 30B, 30C, 31A, and 31B are explanatory diagrams of the semiconductor device manufacturing method according to the fourth embodiment.

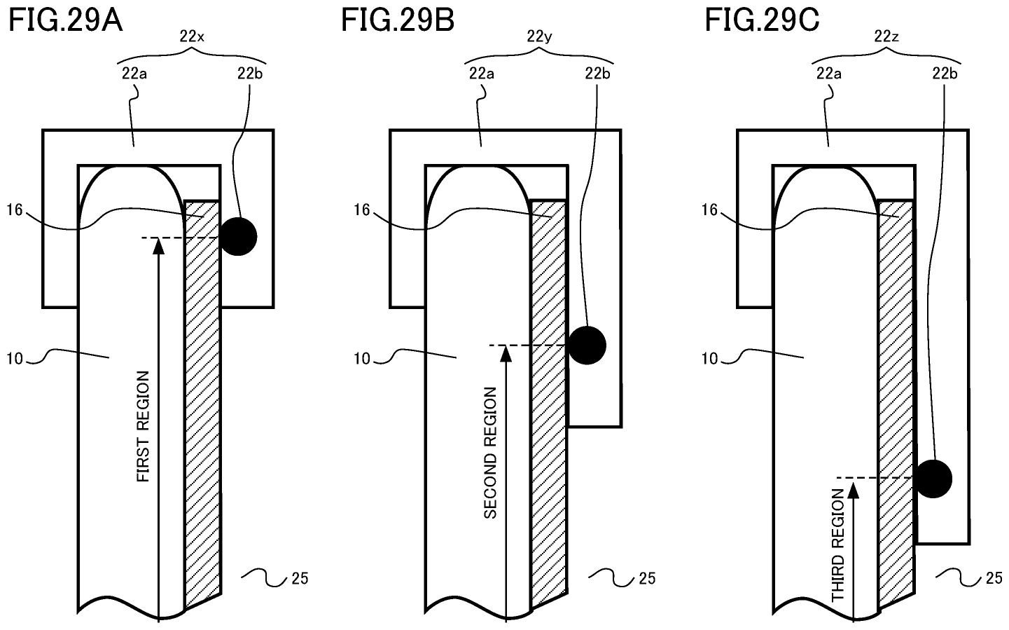

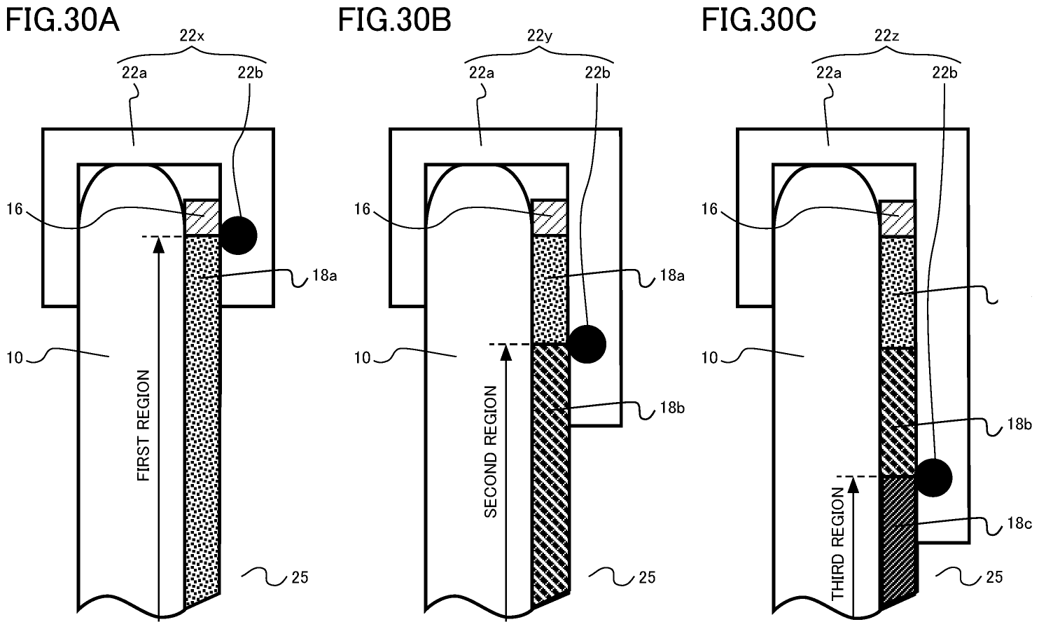

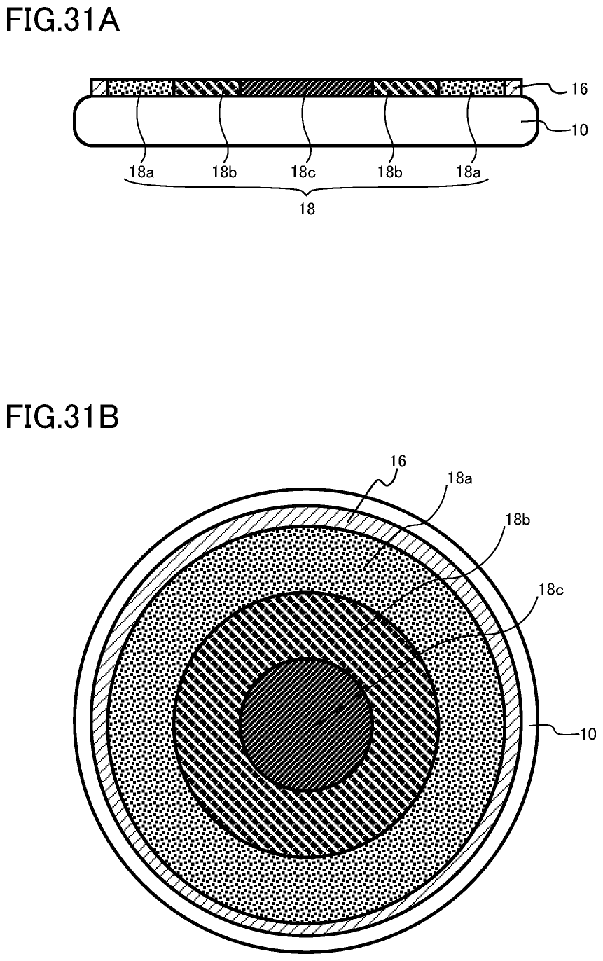

FIGS. 28A, 28B, 28C, 28D, 28E, and 31A are schematic cross-sectional views. FIG. 31B is a schematic top view. FIGS. 29A, 29B, 29C, 30A, 30B, and 30C are explanatory diagrams of an anodization method in the semiconductor device manufacturing method according to the fourth embodiment.

First, the support substrate 10 is prepared (FIG. 28A).

The support substrate 10 is a conductor. The support substrate 10 is, for example, a semiconductor. The support substrate 10 is, for example, a single crystal silicon. The support substrate 10 is, for example, a silicon substrate.

The diameter of the support substrate 10 is, for example, equal to or more than 150 mm and equal to or less than 300 mm.

Then, the polycrystalline silicon layer 16 is formed on the surface of the support substrate 10 (FIG. 28B). The polycrystalline silicon layer 16 is an example of a silicon layer. The support substrate 10 on which the polycrystalline silicon layer 16 is formed is an example of the first substrate.

The polycrystalline silicon layer 16 is formed by using, for example, a CVD method. The thickness of the polycrystalline silicon layer 16 is, for example, equal to or more than 100 nm and equal to or less than 10 μm.

Then, the polycrystalline silicon layer 16 is made porous using an anodization method. For example, the polycrystalline silicon layer 16 is made porous using an apparatus similar to the anodization apparatus 20 shown in FIG. 4 of the first embodiment. By making the polycrystalline silicon layer 16 porous, the porous silicon layer 18 is formed.

When making the polycrystalline silicon layer 16 porous by using the anodization method, a first step, a second step, and a third step are performed.

In the first step, an outer peripheral porous region 18a is formed in the polycrystalline silicon layer 16 (FIG. 28C). In the first step, when forming the polycrystalline silicon layer 16 by using the anodization method, a first substrate holder 22x is used. The outer peripheral porous region 18a is an example of the first porous region.

In the second step, an intermediate porous region 18b is formed in the polycrystalline silicon layer 16 (FIG. 28D). In the second step, when forming the polycrystalline silicon layer 16 by using the anodization method, a second substrate holder 22y is used. The intermediate porous region 18b is an example of the second porous region.

The intermediate porous region 18b is formed inside the outer peripheral porous region 18a. The intermediate porous region 18b is provided in a direction along the surface of the polycrystalline silicon layer 16 with respect to the outer peripheral porous region 18a.

The porosity of the intermediate porous region 18b is higher than the porosity of the outer peripheral porous region 18a.

In the third step, a central porous region 18c is formed in the polycrystalline silicon layer 16 (FIG. 28E). In the third step, when forming the polycrystalline silicon layer 16 by using the anodization method, a third substrate holder 22z is used.

The central porous region 18c is formed inside the intermediate porous region 18b. The central porous region 18c is provided in a direction along the surface of the polycrystalline silicon layer 16 with respect to the intermediate porous region 18b.

The porosity of the central porous region 18c is higher than the porosity of the intermediate porous region 18b.

Between the respective steps of the first step, the second step, and the third step, for example, the substrate is once lifted from the processing tank 21 to replace the substrate holder 22, and then the next step is performed.

FIG. 29A shows the first substrate holder 22x used in the first step, FIG. 29B shows the second substrate holder 22y used in the second step, and FIG. 29C shows the third substrate holder 22z used in the third step. In addition, FIGS. 29A, 29B, and 29C are diagrams before the support substrate 10 is carried into the anodization apparatus 20 to start making the polycrystalline silicon layer 16 porous. That is, FIGS. 29A, 29B, and 29C are diagrams before applying a voltage between the first electrode 23 and the second electrode 24.

The first substrate holder 22x is an example of the first substrate holder. The second substrate holder 22y is an example of the second substrate holder.

When the support substrate 10 is held by the first substrate holder 22x, as shown in FIG. 29A, a portion of the polycrystalline silicon layer 16 in contact with the electrolyte 25 is limited to the first region by the sealing portion 22b. When the first substrate holder 22x is used, for example, a portion of the polycrystalline silicon layer 16 in contact with the electrolyte 25 on the second electrode 24 (FIG. 4) side is limited to the first region. In addition, for example, a portion of the polycrystalline silicon layer 16 in contact with the electrolyte 25 on the cathode side is limited to the first region.

When the support substrate 10 is held by the second substrate holder 22y, as shown in FIG. 29B, a portion of the polycrystalline silicon layer 16 in contact with the electrolyte 25 is limited to the second region by the sealing portion 22b. The second region is inner than the first region.

When the second substrate holder 22y is used, for example, a portion of the polycrystalline silicon layer 16 in contact with the electrolyte 25 on the second electrode 24 (FIG. 4) side is limited to the second region. In addition, for example, a portion of the polycrystalline silicon layer 16 in contact with the electrolyte 25 on the cathode side is limited to the second region.

When the support substrate 10 is held by the third substrate holder 22z, as shown in FIG. 29C, a portion of the polycrystalline silicon layer 16 in contact with the electrolyte 25 is limited to the third region by the sealing portion 22b. The third region is inner than the second region.

When the third substrate holder 22z is used, for example, a portion of the polycrystalline silicon layer 16 in contact with the electrolyte 25 on the second electrode 24 (FIG. 4) side is limited to the third region. In addition, for example, a portion of the polycrystalline silicon layer 16 in contact with the electrolyte 25 on the cathode side is limited to the third region.

FIGS. 30A, 30B, and 30C are explanatory diagrams of making the polycrystalline silicon layer 16 porous. FIG. 30A shows the first step, FIG. 30B shows the second step, and FIG. 30C shows the third step. FIGS. 30A, 30B, and 30C are diagrams after the support substrate 10 has been carried into the anodization apparatus 20 and the polycrystalline silicon layer 16 has been made porous in each step.

In the first step, as shown in FIG. 30A, the polycrystalline silicon layer 16 in the first region inside the sealing portion 22b is made porous to form the outer peripheral porous region 18a. In the second step, as shown in FIG. 30B, the polycrystalline silicon layer 16 in the second region inside the sealing portion 22b is further made porous to form the intermediate porous region 18b. In the third step, as shown in FIG. 30C, the polycrystalline silicon layer 16 in the third region inside the sealing portion 22b is further made porous to form the central porous region 18c.

FIGS. 31A and 31B are schematic diagrams immediately after forming the porous silicon layer 18 by using an anodization method. As shown in FIGS. 31A and 31B, the intermediate porous region 18b is surrounded by the outer peripheral porous region 18a, and the central porous region 18c is surrounded by the intermediate porous region 18b. The porosity of the porous silicon layer 18 increases from the outside to the inside of the porous silicon layer 18.

In the semiconductor device manufacturing method according to the fourth embodiment, the region to be made porous is changed by changing the position of the sealing portion 22b of the substrate holder 22 of the anodization apparatus 20 in each step.

After the porous silicon layer 18 is formed, a three-dimensional NAND flash memory is manufactured by using a method similar to the semiconductor device manufacturing method according to the first embodiment.

For example, when separating the support substrate 10 and the semiconductor substrate 40 from each other, a case is considered in which the porous silicon layer 18 is divided by applying shear stress to the porous silicon layer 18 by rotating the second support part 62 with respect to the first support part 61 as described in the third embodiment. In the semiconductor device manufacturing method according to the fourth embodiment, since the central porous region 18c with a low mechanical strength is present in the central portion of the support substrate 10, the support substrate 10 and the semiconductor substrate 40 are easily divided even when the shear stress applied to the porous silicon layer 18 on the central portion of the support substrate 10 is small.

On the other hand, due to the presence of the outer peripheral porous region 18a with a high mechanical strength in the outer peripheral portion of the support substrate 10, the mechanical strength of the porous silicon layer 18 is maintained. Therefore, it is possible to suppress the breakage of the porous silicon layer 18 during the formation of the memory layer 30.

In addition, since the intermediate porous region 18b having a medium mechanical strength is present in the intermediate portion of the support substrate 10, abrupt changes in the physical properties of the porous silicon layer 18 in the in-plane direction are suppressed. Therefore, for example, the warpage of the support substrate 10 is reduced.

In addition, even if the order of the first step, the second step, and the third step is changed when making the polycrystalline silicon layer 16 porous, the same function and effect can be achieved.

In addition, in the semiconductor device manufacturing method according to the fourth embodiment, the configuration of the substrate holder 22 or the sealing portion 22b is not limited to the configurations shown in FIGS. 29A, 29B, and 29C. Any configuration is acceptable as long as the region where the polycrystalline silicon layer 16 is made porous can be changed in each step.

In the fourth embodiment, the method of making the polycrystalline silicon layer 16 formed on the surface of the support substrate 10 porous has been described as an example. However, the support substrate 10 may be a silicon substrate, and a single crystal silicon layer at the surface layer portion of the support substrate 10 may be made porous.

As described above, according to the semiconductor device manufacturing method according to the fourth embodiment, the in-plane distribution of the mechanical strength of the porous silicon layer is optimized by controlling the in-plane distribution of porosity in the porous silicon layer. Therefore, when manufacturing a semiconductor device by bonding two substrates together, a stable manufacturing process can be realized.

### Fifth Embodiment

A semiconductor device manufacturing method according to a fifth embodiment is different from the semiconductor device manufacturing method according to the third embodiment in that a first region having a first insulating film and a second region, which has a second insulating film that is thinner than the first insulating film or has no insulating film, are formed on the surface of a silicon layer before forming a porous silicon layer and the first region becomes a first porous region and the second region becomes a second porous region when making the silicon layer porous.

The semiconductor device manufacturing method according to the fifth embodiment is different from the semiconductor device manufacturing methods according to the first and third embodiments in that the process of forming a porous silicon layer on the first substrate is different. Hereinafter, the description of the content overlapping the semiconductor device manufacturing methods according to the first and third embodiments may be omitted.

The semiconductor device manufacturing method according to the fifth embodiment is a method for manufacturing a semiconductor device by bonding two substrates together. The semiconductor device is, for example, a semiconductor memory. The semiconductor memory is, for example, a three-dimensional NAND flash memory in which memory cells are arranged in a three-dimensional manner.

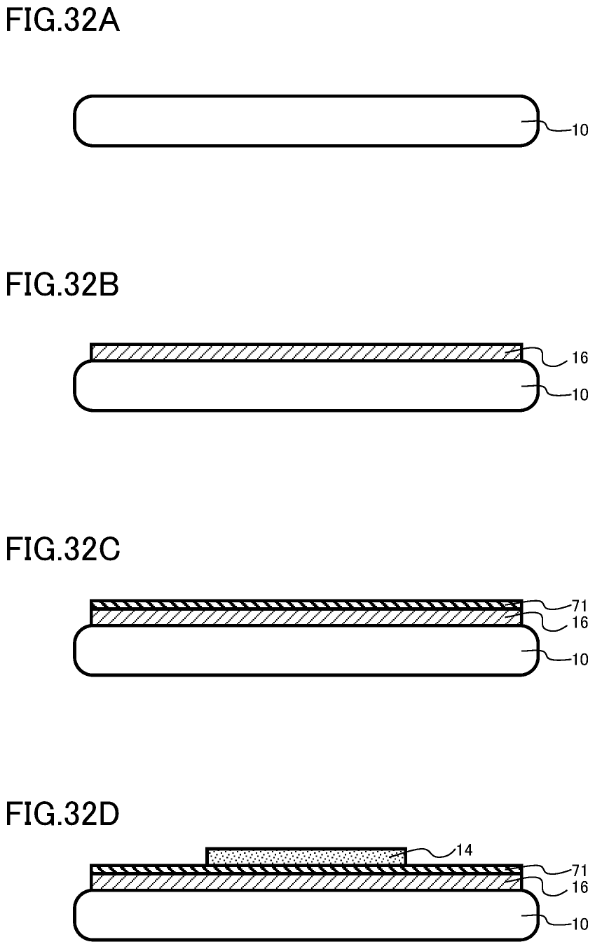

FIGS. 32A, 32B, 32C, 32D, 33A, 33B, 34A, and 34B are explanatory diagrams of the semiconductor device manufacturing method according to the fifth embodiment.

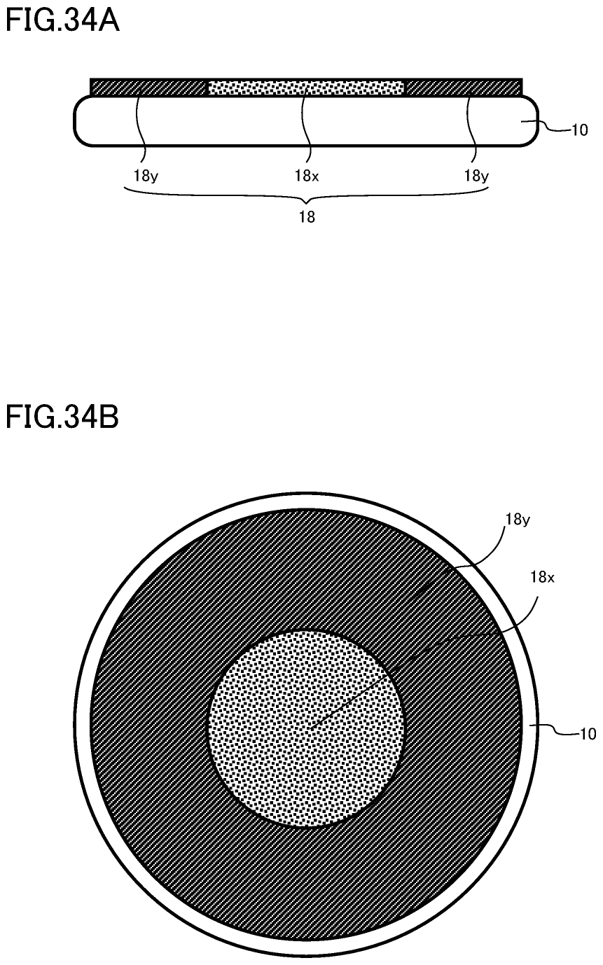

FIGS. 32A, 32B, 32C, 32D, 33A, 33B, and 34A are schematic cross-sectional views. FIG. 34B is a schematic top view.

First, the support substrate 10 is prepared (FIG. 32A).

The support substrate 10 is a conductor. The support substrate 10 is, for example, a semiconductor. The support substrate 10 is, for example, a single crystal silicon. The support substrate 10 is, for example, a silicon substrate.

The diameter of the support substrate 10 is, for example, equal to or more than 150 mm and equal to or less than 300 mm.

Then, the polycrystalline silicon layer 16 is formed on the surface of the support substrate 10 (FIG. 32B). The polycrystalline silicon layer 16 is an example of a silicon layer. The support substrate 10 on which the polycrystalline silicon layer 16 is formed is an example of the first substrate.

The polycrystalline silicon layer 16 is formed by using, for example, a CVD method. The thickness of the polycrystalline silicon layer 16 is, for example, equal to or more than 100 nm and equal to or less than 10 μm.

Then, an insulating film 71 is formed on the surface of the polycrystalline silicon layer 16 (FIG. 32C). The insulating film 71 is formed by using, for example, a CVD method.

The insulating film 71 is, for example, an oxide, a nitride, an oxynitride, or a carbide. The insulating film 71 is, for example, a silicon oxide, a silicon nitride, or a nitrogen-doped silicon carbide.

The thickness of the insulating film 71 is, for example, equal to or more than 1 nm and equal to or less than 100 nm.

Then, the photoresist film 14 is formed so as to cover the central portion of the polycrystalline silicon layer 16 (FIG. 32D). For example, the photoresist film 14 is formed by patterning using a photolithography method.

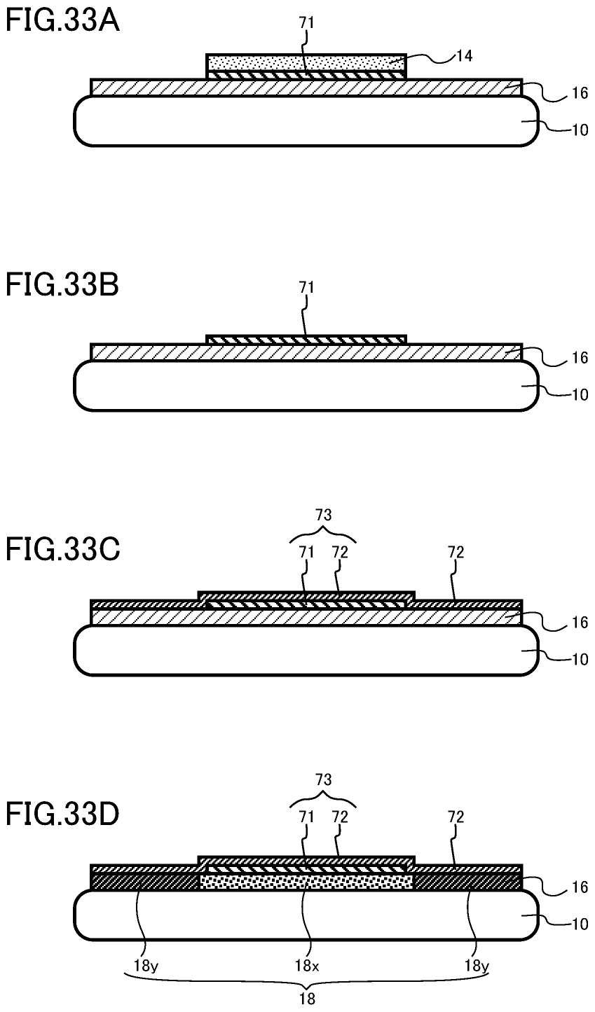

Then, using the patterned photoresist film 14 as a mask, the insulating film 71 on the outer peripheral portion of the support substrate 10 is removed (FIG. 33A). The insulating film 71 is removed by using, for example, a wet etching method.

Then, the photoresist film 14 is removed (FIG. 33B).

Then, an insulating film 72 is formed on the surfaces of the polycrystalline silicon layer 16 and the insulating film 71 (FIG. 33C). The insulating film 72 is formed by using, for example, a CVD method.

The thickness of the insulating film 72 is, for example, equal to or more than 1 nm and equal to or less than 100 nm.

The region where the insulating film 71 and the insulating film 72 are stacked on the surface of the polycrystalline silicon layer 16 is an example of the first region. A stacked film 73 in which the insulating film 71 and the insulating film 72 are stacked is an example of the first insulating film. The region where only the insulating film 72 is stacked on the surface of the polycrystalline silicon layer 16 is an example of the second region. The insulating film 72 formed on the second region is an example of the second insulating film.

The thickness of the insulating film 72 is smaller than the thickness of the stacked film 73 in which the insulating film 71 and the insulating film 72 are stacked.

Then, the polycrystalline silicon layer 16 is made porous by using an anodization method (FIG. 33D). In addition, the anodization method used is the same as the anodization method used in the semiconductor device manufacturing method according to the first embodiment.

By making the polycrystalline silicon layer 16 porous, the porous silicon layer 18 is formed. The porous silicon layer 18 has a void inside.

Then, the insulating film 71 and the insulating film 72 are removed (FIGS. 34A and 34B).

The central portion of the porous silicon layer 18 becomes the low porous region 18x. In addition, the outer peripheral portion of the porous silicon layer 18 becomes the high porous region 18y. The low porous region 18x is an example of the first porous region. The high porous region 18y is an example of the second porous region. The high porous region 18y surrounds the low porous region 18x. The high porous region 18y is provided in a direction along the surface of the polycrystalline silicon layer 16 with respect to the low porous region 18x.

When forming the porous silicon layer 18 using an anodization method, the region where the stacked film 73 is stacked becomes the low porous region 18x. In addition, the region where only the insulating film 72 is formed becomes the high porous region 18y.

The high porous region 18y has a first porosity. In addition, the low porous region 18x has a second porosity. The first porosity is higher than the second porosity.

When forming the porous silicon layer 18 using an anodization method, a larger amount of current flows through a region where the thickness of the insulating film is small than through a region where the thickness of the insulating film is large. Therefore, the region where the stacked film 73 is formed becomes the low porous region 18x. In addition, the region where only the insulating film 72 is stacked becomes the high porous region 18y.

After the porous silicon layer 18 is formed, a three-dimensional NAND flash memory is manufactured by using a method similar to the semiconductor device manufacturing method according to the first embodiment.

In the semiconductor device manufacturing method according to the fifth embodiment, the low porous region 18x is provided in the central portion of the support substrate 10, and the high porous region 18y is provided in the outer peripheral portion of the support substrate 10. The porosity of the high porous region 18y is higher than the porosity of the low porous region 18x. The mechanical strength of the high porous region 18y with a high porosity is lower than that of the low porous region 18x with a low porosity.

For example, a case is considered in which when separating the support substrate 10 and the semiconductor substrate 40 from each other, the porous silicon layer 18 is divided by pressing a wedge-shaped jig from the side toward the porous silicon layer 18. In the semiconductor device manufacturing method according to the fifth embodiment, since the high porous region 18y with a low mechanical strength is present in the outer peripheral portion of the support substrate 10, the support substrate 10 and the semiconductor substrate 40 are easily divided.

On the other hand, due to the presence of the low porous region 18x with a high mechanical strength in the central portion of the support substrate 10, the mechanical strength of the porous silicon layer 18 is maintained. Therefore, it is possible to suppress the breakage of the porous silicon layer 18 during the formation of the memory layer 30.

In the fifth embodiment, the method of making the polycrystalline silicon layer 16 porous on the surface of the support substrate 10 has been described as an example. However, the support substrate 10 may be a silicon substrate, and a single crystal silicon layer at the surface layer portion of the support substrate 10 may be made porous.

In the fifth embodiment, the method in which an insulating film is formed in both the first region and the second region has been described as an example. However, it is also possible not to provide an insulating film in the second region, for example.

In addition, in the fifth embodiment, the method of providing two regions with different insulating film thicknesses has been described as an example. However, it is also possible to provide three or more regions with different insulating film thicknesses.

In addition, in the fifth embodiment, a pattern in which the high porous region 18y surrounds the low porous region 18x has been described as an example. However, it is also possible to form other patterns.

As described above, according to the semiconductor device manufacturing method according to the fifth embodiment, the in-plane distribution of the mechanical strength of the porous silicon layer is optimized by controlling the in-plane distribution of porosity in the porous silicon layer. Therefore, when manufacturing a semiconductor device by bonding two substrates together, a stable manufacturing process can be realized.

In the first to fifth embodiments, a three-dimensional NAND flash memory is shown as an example of the semiconductor device to be manufactured, a memory cell array is shown as an example of the first electronic circuit, and a control circuit that controls the operation of the memory cell array is shown as an example of the second electronic circuit. However, the semiconductor device to be manufactured, the first electronic circuit, and the second electronic circuit are not limited to the examples described above. For example, the semiconductor device to be manufactured may be an optical sensor, the first electronic circuit may be a light receiving part, and the second electronic circuit may be a control circuit for the light receiving part.

While certain embodiments have been described, these embodiments have been presented by way of example only, and are not intended to limit the scope of the inventions. Indeed, the semiconductor device manufacturing method described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
forming an insulating film on an outer peripheral portion of a surface of a first substrate;
forming a silicon layer in contact with the surface inside the insulating film after the forming the insulating film; and
forming a porous silicon layer by making the silicon layer inside the insulating film porous using an anodization method.

2. The semiconductor device manufacturing method according to claim 1,
wherein the silicon layer is a polycrystalline silicon.

3. The semiconductor device manufacturing method according to claim 2, further comprising:
removing the silicon layer formed on the insulating film.

4. The semiconductor device manufacturing method according to claim 1,
wherein the first substrate is a silicon substrate.

5. The semiconductor device manufacturing method according to claim 1,
wherein the silicon layer is a single crystal silicon layer formed by using an epitaxial growth method.

6. The semiconductor device manufacturing method according to claim 1,
wherein the insulating film is a silicon oxide, a silicon nitride, or a nitrogen-doped silicon carbide.

7. The semiconductor device manufacturing method according to claim 1, further comprising:
forming a first electronic circuit on the porous silicon layer after using the anodization method;
preparing a second substrate having a second electronic circuit;
bonding the first substrate and the second substrate together so that the first electronic circuit and the second electronic circuit being connected to each other; and
separating the first electronic circuit and the first substrate from each other with the porous silicon layer as a boundary.

8. The semiconductor device manufacturing method according to claim 7,
wherein the first electronic circuit includes a memory cell array, and the second electronic circuit includes a control circuit for controlling an operation of the memory cell array.

9. A semiconductor device manufacturing method, comprising:
preparing a first substrate, a surface of an outer peripheral portion of the first substrate being an insulating film and a surface disposed inside the outer peripheral portion being a silicon layer; and
forming a porous silicon layer by making the silicon layer inside the insulating film porous using an anodization method.

10. The semiconductor device manufacturing method according to claim 9,
wherein the first substrate is a silicon substrate, and the silicon layer is a surface portion of the silicon substrate.

11. The semiconductor device manufacturing method according to claim 9,
wherein the silicon layer is a silicon layer formed by using a chemical vapor deposition method.

12. The semiconductor device manufacturing method according to claim 9,
wherein the insulating film is a silicon oxide, a silicon nitride, or a nitrogen-doped silicon carbide.

13. The semiconductor device manufacturing method according to claim 9, further comprising:
forming a first electronic circuit on the porous silicon layer after using the anodization method;
preparing a second substrate having a second electronic circuit;
bonding the first substrate and the second substrate together so that the first electronic circuit and the second electronic circuit being connected to each other; and
separating the first electronic circuit and the first substrate from each other with the porous silicon layer as a boundary.

14. The semiconductor device manufacturing method according to claim 13,
wherein the first electronic circuit includes a memory cell array, and the second electronic circuit includes a control circuit for controlling an operation of the memory cell array.

15. A semiconductor device manufacturing method, comprising:
preparing a first substrate, a first surface of the first substrate having a silicon layer;
and
forming a porous silicon layer having a first porous region having a first porosity and a second porous region provided in a direction along the surface with respect to the first porous region and having a second porosity higher than the first porosity, by an anodization method using a holder which covers at least an outer region of the first surface.

16. The semiconductor device manufacturing method according to claim 15,
wherein the second porous region surrounds the first porous region.

17. The semiconductor device manufacturing method according to claim 15,
wherein the first porous region surrounds the second porous region.

18. The semiconductor device manufacturing method according to claim 15, further comprising:
forming a first region and a second region having an impurity concentration higher than an impurity concentration of the first region by implanting impurities into the silicon layer using an ion implantation method before the forming the porous silicon layer,
wherein the first region becomes the first porous region and the second region becomes the second porous region in the forming the porous silicon layer.

19. The semiconductor device manufacturing method according to claim 15,
wherein, the holder includes a first substrate holder and a second substrate holder, in the forming the porous silicon layer,
using the first substrate holder for limiting a portion of the silicon layer in contact with an electrolyte to a first region,
using the second substrate holder for limiting a portion of the silicon layer in contact with an electrolyte to a second region inside the first region, and
the second region becomes the second porous region, and the first region outside the second region becomes the first porous region.

20. The semiconductor device manufacturing method according to claim 15, further comprising:
forming a first region having a first insulating film and a second region having a second insulating film thinner than the first insulating film or having no insulating film on the surface of the silicon layer before the forming the porous silicon layer, and
wherein the first region becomes the first porous region and the second region becomes the second porous region in the forming the porous silicon layer.
